(19) United States
(12) Patent Application Publication
(10) Pub. No.: US 2024/0426954 A1
(43) Pub. Date: Dec. 26, 2024

(54) DEVICES FOR PROCESSING MAGNETIC RESONANCE SIGNALS

(71) Applicant: SHANGHAI UNITED IMAGING HEALTHCARE CO., LTD., Shanghai (CN)

(72) Inventors: Xiaolei GUAN, Shanghai (CN); Kehan ZHOU, Shanghai (CN); Yongyang LI, Shanghai (CN); Fangyan HOU, Shanghai (CN); Wei ZHANG, Shanghai (CN)

(73) Assignee: SHANGHAI UNITED IMAGING HEALTHCARE CO., LTD., Shanghai (CN)

(21) Appl. No.: 18/827,618

(22) Filed: Sep. 6, 2024

Related U.S. Application Data
(63) Continuation of application No. PCT/CN2023/082207, filed on Mar. 17, 2023.

(30) Foreign Application Priority Data
Mar. 17, 2022 (CN) 202210262916.9
Jun. 17, 2022 (CN) 202210689306.7

(51) Int. Cl. G01R 33/36

(52) U.S. Cl. CPC G01R 33/3621

(57) ABSTRACT

The present disclosure provides a magnetic resonance signal processing device. The device may include: a signal receiving unit configured to obtain a received magnetic resonance signal, wherein at least part of the magnetic resonance signal is generated by exciting one or more specific nuclides; an analog-to-digital converter configured to perform an analog-to-digital conversion on the magnetic resonance signal; and a control unit configured to obtain a digital output signal of the magnetic resonance signal by processing the magnetic resonance signal after the analog-to-digital conversion.

### CROSS-REFERENCE TO RELATED APPLICATIONS

This application is a continuation of International Patent Application No. PCT/CN2023/082207, filed on Mar. 17, 2023, which claims priority to Chinese Patent Application No. 202210689306.7, filed on Jun. 17, 2022, and Chinese Patent Application No. 202210262916.9, filed on Mar. 17, 2022, the content of each of which is hereby incorporated by reference.

### TECHNICAL FIELD

The present disclosure relates to a field of magnetic resonance imaging technology, and in particular, to a magnetic resonance signal processing device.

### BACKGROUND

Magnetic resonance signal is a signal released by at least one nuclide of a target object in a form of a wireless wave under actions of a magnetic field (B0 field) and a radio frequency field (B1 field). The magnetic resonance signal may be used both for nuclear magnetic resonance imaging and for magnetic resonance spectroscopy analysis or magnetic resonance spectroscopy imaging. In the magnetic resonance spectroscopy analysis or magnetic resonance spectroscopy imaging, both a relatively high dynamic range and a relatively high signal-to-noise ratio are required. In addition, a signal acquisition device of a magnetic resonance device usually adopts a receiving link designed using a traditional super heterodyne architecture currently, which often includes a large number of components, resulting in a relatively long receiving link and a waste of hardware resources.

In some scenarios, an integration degree of the magnetic resonance device may need to be improved, and/or a relatively high dynamic range and a relatively high signal-to-noise ratio need to be achieved when processing the magnetic resonance signal.

### SUMMARY

One aspect of the present disclosure may provide a signal acquisition device. The signal acquisition device may include: a signal receiving unit configured to obtain a received magnetic resonance signal, wherein at least part of the magnetic resonance signal is generated by exciting one or more specific nuclides; an analog-to-digital converter configured to perform an analog-to-digital conversion on the magnetic resonance signal; and a control unit configured to obtain a digital output signal of the magnetic resonance signal by processing the magnetic resonance signal after the analog-to-digital conversion.

One aspect of the present disclosure may provide a magnetic resonance signal processing device. The magnetic resonance signal processing device may be configured to process a magnetic resonance spectrum signal collected by a first front-end receiving device. The magnetic resonance signal processing device may include: a power divider configured to divide the magnetic resonance spectrum signal into at least two power-divided signals; at least two analog-to-digital converters configured to convert the power-divided signals into power-divided digital signals; and a control unit configured to obtain a digital output signal corresponding to the magnetic resonance spectrum signal by adding the power-divided digital signals.

One aspect of the present disclosure may provide a magnetic resonance signal processing device. The magnetic resonance signal processing device may be configured to process a magnetic resonance spectrum signal collected by a first front-end receiving device. The magnetic resonance signal processing device may include: an amplification circuit configured to amplify the magnetic resonance spectrum signal; a frequency mixing circuit configured to divide an amplified magnetic resonance spectrum signal into a first signal and a second signal; a power divider configured to divide the first signal into at least two first power-divided signals and divide the second signal into at least two second power-divided signals, wherein the device is configured to be detachably connected to at least two analog-to-digital conversion circuitconverters and a control unit, each of the analog-to-digital conversion circuitconverters is configured to convert one of the at least two first power-divided signals into a first power-divided digital signal, or convert one of the at least two second power-divided signals into a second power-divided digital signal, and the control unit is configured to obtain a digital output signal corresponding to the magnetic resonance spectrum signal by respectively adding at least two first power-divided digital signals and at least two second power-divided digital signals.

One aspect of the present disclosure may provide a magnetic resonance signal processing device. The magnetic resonance signal processing device may include: a third signal-receiving unit configured to process a first magnetic resonance signal with a specific frequency; a fourth signal-receiving unit configured to process a second magnetic resonance signal obtained according to a fifth control signal, the second magnetic resonance signal corresponding to one of a plurality of magnetic resonance frequencies; at least two analog-to-digital conversion circuitconverters configured to perform an analog-to-digital conversion on the first magnetic resonance signal or the second magnetic resonance signal; and a control unit configured to generate a digital output signal corresponding to the first magnetic resonance signal by processing the first magnetic resonance signal after the analog-to-digital conversion, or generate a digital output signal corresponding to the second magnetic resonance signal by processing the second magnetic resonance signal after the analog-to-digital conversion.

### BRIEF DESCRIPTION OF THE DRAWINGS

The present disclosure may be further described in terms of exemplary embodiments, which may be described in detail with reference to the drawings. These embodiments are non-limiting exemplary embodiments, in which like reference numerals represent similar structures, and wherein:

FIG. 1 is a schematic diagram illustrating an exemplary medical system according to some embodiments of the present disclosure;

FIG. 2 is a block diagram illustrating an exemplary medical system according to some embodiments of the present disclosure;

FIG. 3 is a schematic diagram illustrating a structure of a signal acquisition device according to some embodiments of the present disclosure;

FIG. 4 is a schematic diagram illustrating a structure of a signal acquisition device according to some embodiments of the present disclosure;

FIG. 5 is a schematic diagram illustrating exemplary structures of a radio frequency transformer according to some embodiments of the present disclosure;

FIG. 6A is a schematic diagram illustrating a structure of a parallel adjustable capacitor unit according to some embodiments of the present disclosure;

FIG. 6B is a schematic diagram illustrating a structure of a series adjustable capacitor unit according to some embodiments of the present disclosure;

FIG. 7 is a flowchart illustrating a signal acquisition process according to some embodiments of the present disclosure;

FIG. 8 is a schematic diagram illustrating an exemplary magnetic resonance signal processing device according to some embodiments of the present disclosure;

FIG. 9 is an exemplary schematic diagram illustrating an exemplary magnetic resonance signal processing device according to some embodiments of the present disclosure;

FIG. 10 is a schematic diagram illustrating a control unit according to some embodiments of the present disclosure;

FIG. 11 is an exemplary schematic diagram illustrating switch units according to some embodiments of the present disclosure;

FIG. 12a is an exemplary schematic diagram illustrating a first amplification circuit according to some embodiments of the present disclosure;

FIG. 12b is an exemplary schematic diagram illustrating another first amplification circuit according to some embodiments of the present disclosure; and

FIG. 13 is a flowchart illustrating an exemplary process according to some embodiments of the present disclosure.

### DETAILED DESCRIPTION

In the following detailed description, numerous specific details are set forth by way of examples in order to provide a thorough understanding of the relevant disclosure. Obviously, the drawings described below are only some examples or embodiments of the present disclosure. Those skilled in the art, without further creative efforts, may apply the present disclosure to other similar scenarios according to these drawings. It should be understood that the purposes of these illustrated embodiments are only provided to those skilled in the art to practice the application, and are not intended to limit the scope of the present disclosure. Unless obviously obtained from the context or the context illustrates otherwise, the same numeral in the drawings refers to the same structure or operation.

It will be understood that the terms “system,” “engine,” “unit,” “module,” and/or “block” used herein are one method to distinguish different components, elements, parts, sections, or assemblies of different levels in ascending order. However, the terms may be displaced by other expressions if they may achieve the same purpose.

The terminology used herein is for the purposes of describing particular examples and embodiments only and is not intended to be limiting. As used herein, the singular forms “a,” “an,” and “the” may be intended to include the plural forms as well unless the context clearly indicates otherwise. It will be further understood that the terms “include” and/or “comprise,” when used in this disclosure, specify the presence of integers, devices, behaviors, stated features, steps, elements, operations, and/or components but do not exclude the presence or addition of one or more other integers, devices, behaviors, features, steps, elements, operations, components, and/or groups thereof.

The flowcharts used in the present disclosure illustrate operations that systems implement according to some embodiments of the present disclosure. It is to be expressly understood the operations of the flowcharts may not be implemented in order. Conversely, the operations may be implemented in an inverted order or simultaneously. Moreover, one or more other operations may be added to the flowcharts. One or more operations may be removed from the flowcharts.

A signal acquisition device in one or more embodiments of the present disclosure may acquire one or more magnetic resonance signals, so as to be applied to various scenarios that require signal analysis. For example, a digital output signal (e.g., K-Space data, a spectrogram of chemical shift values) corresponding to magnetic resonance signals may be provided for disease assessment or scientific research analysis in a medical device. As another example, detection information (e.g., material composition information and material distribution information) corresponding to the magnetic resonance signal(s) may be provided in a detection device. In some embodiments, the signal acquisition device may not only be applied to a magnetic resonance imaging (MRI) device or nuclear magnetic resonance (NMR) device but also may be applied to other devices (e.g., a geological detection device and a chemical substance analysis device) that need to analyze magnetic resonance signals. In some embodiments, the signal acquisition device in one or more embodiments of the present disclosure may not only acquire magnetic resonance signals but also acquire other wireless signals, such as communication signals used to transmit data, wireless electromagnetic waves used to transmit energy, etc. The type of the collected signal may be selected according to requirements.

The signal acquisition device provided by the embodiments of the present disclosure may include: a signal obtaining module, a signal matching module, an analog-to-digital converter, and a control module. The signal obtaining module may be configured to obtain a magnetic resonance signal, at least part of which may be generated by exciting one or more specific nuclides. The signal matching module may include an adjustable capacitance unit and a radio frequency transformer. The adjustable capacitance unit may be configured to adjust a capacitance value according to a first control signal corresponding to an instruction of a host computer to cooperate with the radio frequency transformer to receive the magnetic resonance signal and convert the magnetic resonance signal into an analog differential signal. The analog-to-digital converter may be configured to convert the analog differential signal into a digital signal. The control module may be configured to process the digital signal to generate K-space data corresponding to the magnetic resonance signal. In this way, a receiving link may be designed based on a direct sampling architecture of the analog-to-digital converter. There may be no need to set a mixer in the receiving link, and signal demodulation can be performed in a digital domain to generate the K-space data corresponding to the magnetic resonance signal, thereby shortening the receiving link, reducing an overall volume of the signal acquisition device, and improving an integration degree.

In addition, the signal matching module may select a specific narrowband signal for transmission under broadband through a cooperation of the adjustable capacitor unit and the radio frequency transformer, which may realize broadband tuning and matching with a simple architecture. At the same time, the signal matching module may also slow down the intrusion of radio frequency interference through a narrow receiving frequency band, so that the signal acquisition device can work stably.

Furthermore, when it is necessary to obtain magnetic resonance signals generated based on the excitation of other specific nuclides, the signal acquisition device may not need to replace an entire receiving link, and may replace the signal acquisition module and adjust the capacitance value of the adjustable capacitance unit, so that the adjustable capacitor unit may cooperate with the radio frequency transformer to complete the adjustment of the receiving frequency band, thereby achieving a purpose of receiving a plurality of different magnetic resonance signals using the same link architecture.

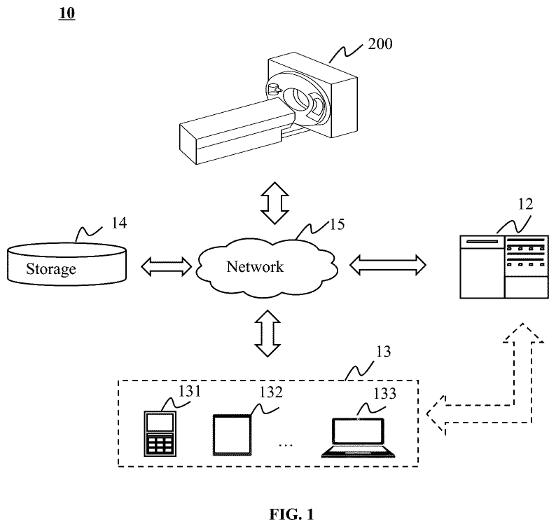

FIG. 1 is a schematic diagram illustrating an exemplary medical system 10 according to some embodiments of the present disclosure. As shown in FIG. 1, in some embodiments, the medical system 10 may include an imaging device 200, a processing device 12, a terminal 13, a storage device 14, and a network 15.

The imaging device 200 refers to a device that may reproduce an internal structure of a target object as an image using different imaging modalities in medicine. In some embodiments, the target object may be a living thing (e.g., a patient, or an animal) or an artificial object (e.g., a phantom). The target object may be a specific part (e.g., an organ and/or tissues) of the patient. In some embodiments, the imaging device 200 may be any medical device that contains detectors and uses radionuclides to image or treat designated body parts of the target object. For example, the imaging device 200 may include a magnetic resonance imaging device. Merely by way of example, the imaging device 200 may be an MRI device, a magnetic resonance-computed tomography imaging (MRI-CT) device, a positron emission tomography-magnetic resonance imaging (PET-MRI) device, a single photon emission computed tomography-magnetic resonance imaging (SPECT-MRI) device, a digital subtraction angiography-magnetic resonance imaging (DSA-MRI) device, etc. The imaging device 200 provided above may be for illustrative purposes only, not limiting its scope.

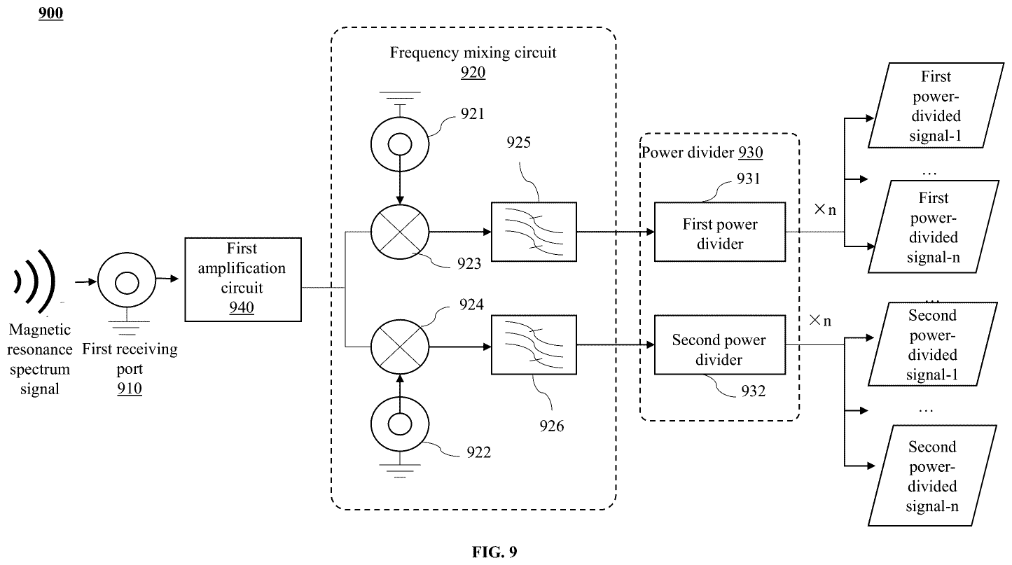

In some embodiments, the imaging device 200 may generate a magnetic resonance signal for MRI (i.e., a magnetic resonance imaging signal) and/or generate a magnetic resonance signal for spectroscopy analysis and/or spectroscopy imaging (i.e., a magnetic resonance spectrum signal). The magnetic resonance signal may be received and processed by a signal acquisition device 100 or a signal processing device (e.g., the MR signal processing device 800 in FIG. 8) shown in some embodiments of the present disclosure to generate magnetic resonance images and/or be used for spectroscopy analysis. In some embodiments, the imaging device 200 may obtain medical image data through scanning and send the medical image data to the processing device 12. The imaging device 200 may receive instructions sent by a doctor through the terminal 13, and perform related operations (e.g., MR imaging) according to the instructions. In some embodiments, the imaging device 200 may exchange data and/or information with other components (e.g., the processing device 12, the storage device 14, the terminal 13) in the medical system 10 through the network 15. In some embodiments, the imaging device 200 may be directly connected to the other components in the medical system 10.

The processing device 12 may process data and/or information obtained from other devices or components of the system. In some embodiments, the processing device 12 may process medical image data obtained from the imaging device 200. In some embodiments, the processing device 12 may obtain data and/or information stored in the storage device 14. In some embodiments, the processing device 12 may include one or more sub-processing devices (e.g., a single-core processing device or a multi-core processing device).

The storage device 14 may store data or information generated by other devices. In some embodiments, the storage device 14 may store data and/or information generated by other components in the system (e.g., the imaging device 200, the processing device 12). The storage device 14 may include one or more storage components, and each storage component may be an independent device or a part of other devices. The storage device may be local or implemented via a cloud.

The terminal 13 may control operations of the imaging device 200. The doctor may issue an operation instruction to the imaging device 200 through the terminal 13 to make the imaging device 200 complete a specified operation, such as performing MR imaging on a specified body part of the patient. In some embodiments, the terminal 13 may be a mobile device 131, a tablet computer 132, a laptop computer 133, a desktop computer, or other devices with input and/or output functions, or the like, or any combination thereof. In some embodiments, the signal acquisition device 100 or the signal processing device (e.g., the MR signal processing device 800 in FIG. 8) shown in some embodiments of the present disclosure may be set in the imaging device 200 or the processing device 12, or implemented by part components in the processing device 12. The signal acquisition device 100 or the signal processing device (e.g., the MR signal processing device 800 in FIG. 8) may also be implemented through a stand-alone terminal 13.

The network 15 may connect various components of the medical system 10 and/or connect parts of the medical system 10 with external resources. In some embodiments, one or more components in the medical system 10 (e.g., the imaging device 200, the processing device 12, the storage device 14, the terminal 13) may send data and/or information to other components via the network 15. In some embodiments, the network 15 may be any one or more of a wired network or a wireless network.

It should be noted that the above description may be provided for illustrative purposes only and may be not intended to limit the scope of the present disclosure. Those skilled in the art may make various changes and modifications under the guidance of the contents of the present disclosure. The features, structures, methods, and other features of the exemplary embodiments described in the present disclosure may be combined in various ways to obtain additional and/or alternative exemplary embodiments. For example, the processing device 12 may be a device based on a cloud computing platform, such as a public cloud, a private cloud, a community, a hybrid cloud, or the like. However, these changes and modifications may not depart from the scope of the present disclosure.

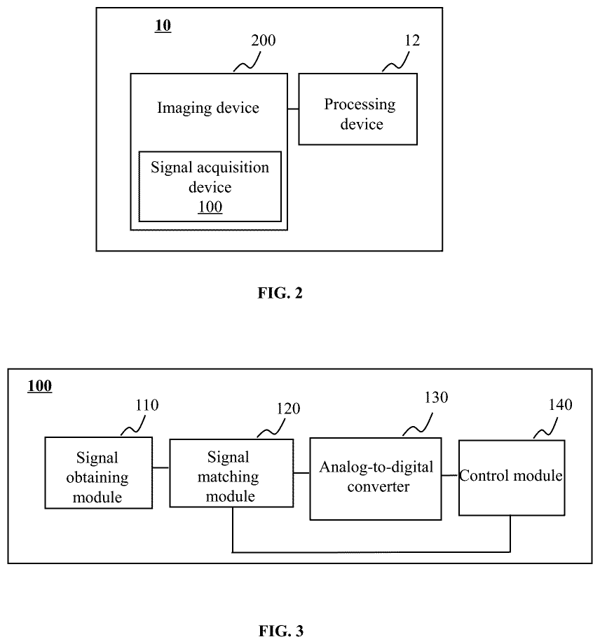

FIG. 2 is a block diagram illustrating an exemplary medical system 10 according to some embodiments of the present disclosure. In some embodiments, as shown in FIG. 2, the medical system 10 may include the imaging device 200 and the processing device 12. The signal acquisition device 100 may be connected to the processing device 12. The signal acquisition device 100 may be part of the imaging device 200 and configured to collect a magnetic resonance signal and output K-space data corresponding to the magnetic resonance signal. The processing device 12 may be configured to output image information corresponding to the K-space data.

The signal acquisition device 100 may be a device for obtaining a magnetic resonance signal. In some embodiments, the magnetic resonance signal may be an electromagnetic wave reflected from an object to be measured. The magnetic resonance signal may undergo different attenuation in different structural environments inside the material, thereby reflecting an internal structure of the object to be measured. For example, a magnetic resonance signal reflected from human tissues may reflect an internal structure of a human body. In some embodiments, at least part of the magnetic resonance signal may be generated by exciting a plurality of specific nuclides, so that the magnetic resonance signal may carry specific nuclide information, and the nuclide information may include a resonance frequency (i.e., a nuclide frequency) corresponding to the nuclide, a signal amplitude, and other information.

In some embodiments, the signal acquisition device 100 may include a signal receiving unit, an analog-to-digital converter, and a control unit. The signal receiving unit may be configured to process a received magnetic resonance signal, wherein at least part of the magnetic resonance signal is generated by exciting one or more specific nuclides. The analog-to-digital converter may be configured to perform an analog-to-digital conversion on the magnetic resonance signal. The control unit may be configured to obtain a digital output signal of the magnetic resonance signal by processing the magnetic resonance signal after the analog-to-digital conversion.

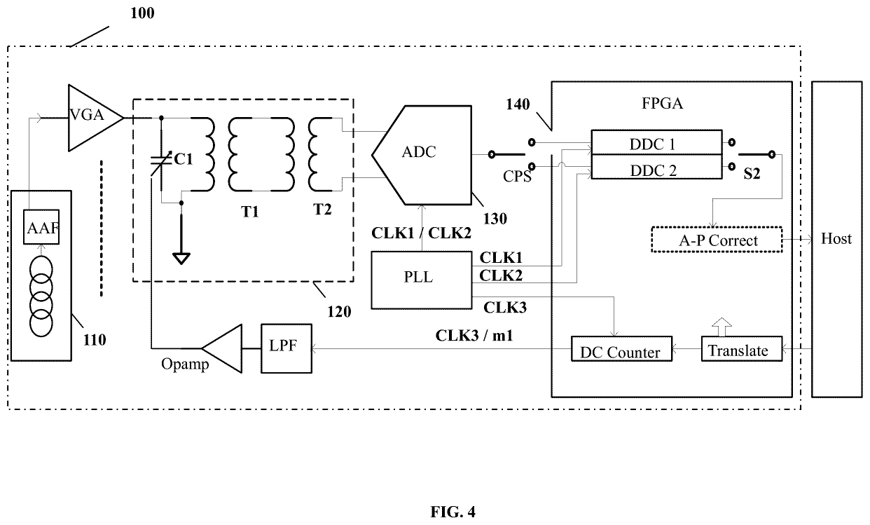

In some embodiments, the signal acquisition device 100 may collect a magnetic resonance signal of a specific nuclide frequency. For example, the signal acquisition device 100 may collect magnetic resonance signals corresponding to multinuclear nuclide frequencies (e.g., 1H nuclide frequency, 3H nuclide frequency, and 19F nuclide frequency). In some embodiments, the signal receiving unit may perform a signal processing (e.g., differential operation or power division) on the received magnetic resonance signal. In some embodiments, the magnetic resonance signal may include a magnetic resonance spectrum signal and/or a magnetic resonance imaging signal. In some embodiments, the signal acquisition device (e.g., the signal acquisition device 100 shown in FIG. 3) may perform extraction, filtering, and demodulation on the magnetic resonance signal (e.g., the magnetic resonance imaging signal), and output the K-space data corresponding to the magnetic resonance signal. In some embodiments, the signal acquisition device (e.g., the magnetic resonance signal processing device 800 shown in FIG. 8) may also perform the power division and re-addition on the magnetic resonance signal (e.g., the magnetic resonance spectrum signal) to obtain a spectrogram of chemical shift values corresponding to the magnetic resonance signal.

In some embodiments, the digital output signal may include K-space data and image data (e.g., a spectrogram). The K-space data may be spatial data obtained from echoes (e.g., magnetic resonance signals) of a measured object. In some embodiments, the k-space data may include spatial data of one or more image slices of the measured object, so that the k-space data may be disposed in an array, e.g., K-space. Each K-space data item (or referred to as a K-space data point) may provide frequency and phase information of the magnetic resonance signal. In some embodiments, the K-space data may be reconstructed to obtain a magnetic resonance image. The spectrogram may be a kind of image data obtained by a magnetic resonance spectrometer (such as the signal acquisition device 100) according to the magnetic resonance signal. In some embodiments, when the magnetic resonance spectrometer is used to analyze compounds, the spectrogram may be a hydrogen spectrogram, a carbon spectrogram, or several two-dimensional spectrograms. When the magnetic resonance spectrometer is used in a medical device, the spectrogram may be a magnetic resonance spectrum (MRS spectrum) or a living body spectrum.

In some embodiments, the signal acquisition device 100 may output not only K-space data but also other image data (e.g., grayscale data, three-dimensional image data, and a spectrogram). A specific type of the image data may be selected according to requirements. For specific implementation manners of the signal acquisition device 100, please refer to relevant descriptions in FIGS. 2-6B below, which may not be repeated here.

The processing device 12 may be an electronic device that constructs an image. In some embodiments, the processing device 12 may perform image reconstruction according to the K-space data, and output image information corresponding to the magnetic resonance signal. In some embodiments, the processing device 12 may be an electronic device (e.g., a host computer and a terminal device) with an image processing function. In some embodiments, the processing device 12 may perform the image reconstruction through an image processing technology such as projection reconstruction, shading recovery shape, stereo vision reconstruction, and laser ranging reconstruction. A specific type of the image processing technology may be selected according to a type of magnetic resonance signal collected. For example, the processing device 12 may generate an image based on the K-space data through inverse Fourier transform.

In some embodiments, the aforementioned imaging device 200 may be a magnetic resonance device. The magnetic resonance device may include one or more components such as a main magnet, a gradient coil, a radio frequency coil, a control device, a spectrometer, and a table. In some embodiments, the magnetic resonance device may include one or more of an MRI device, an NMR device, a magnetic resonance spectroscopy (MRS) device, and a magnetic resonance spectroscopy imaging (MRSI) device. In some embodiments, the imaging device 200 may use a chemical shift difference of the magnetic resonance signal with the nuclide information to identify spectral components of different chemical components, and output image information corresponding to the magnetic resonance signal.

In some embodiments, for a magnetic resonance signal of a nuclide, different strengths of a main static magnetic field (B0 field) of the imaging device 200 may correspond to different working frequencies. For example, the strength of the main static magnetic field of the imaging device 200 may have a proportional linear relationship with the working frequency. The strength of the B0 field of the NMR device may include 4.7 T, 7 T, 9.4 T, 11.7 T, 14.1 T, etc. Correspondingly, the 1H nuclide frequency may be around 200 MHz, 300 MHz, 400 MHz, 500 MHz, or 600 MHz, respectively.

It should be noted that the signal acquisition device 100 may not only be applied to the imaging device 200 but also may be applied to other systems that need to acquire signals. For example, the signal acquisition device 100 may be applied to a geological detection device to acquire a plurality of magnetic resonance signals, and output geological distribution information corresponding to the magnetic resonance signals. As another example, the signal acquisition device 100 may be applied to a chemical substance analysis device, which may obtain magnetic resonance signals reflected from a plurality of substances to be analyzed, and output information (such as material composition and distribution) corresponding to the magnetic resonance signals.

In some embodiments, the signal acquisition device 100 may be a device independent from the imaging device 200. In some embodiments, the processing device 12 may be part of the imaging device 200 or the signal acquisition device 100.

FIG. 3 is a schematic diagram illustrating a structure of a signal acquisition device 100 according to some embodiments of the present disclosure.

In some embodiments, the signal receiving unit may include a signal obtaining module 110 and a signal matching module 120. As shown in FIG. 3, the signal acquisition device 100 may include: the signal obtaining module 110, the signal matching module 120, an analog-to-digital converter 130, and a control module 140. The signal obtaining module 110 may be connected to the signal matching module 120. The signal obtaining module 110 may be configured to obtain a magnetic resonance signal carrying specific nuclide information. The signal matching module 120 may include an adjustable capacitance unit and a radio frequency transformer connected to each other, and the adjustable capacitance unit may be configured to adjust a capacitance value according to a first control signal to cooperate with the radio frequency transformer to receive the magnetic resonance signal carrying the specific nuclide information and convert the magnetic resonance signal into an analog differential signal. The signal matching module 120 may be connected to the analog-to-digital converter 130, and the analog-to-digital converter 130 may be configured to convert the analog differential signal into a digital signal. The analog-to-digital converter 130 may be connected to the control module 140, and the control module 140 may be configured to process the digital signal to generate K-space data corresponding to the magnetic resonance signal. In some embodiments, the control module 140 may include an analysis unit, and the analysis unit may be configured to analyze an instruction of a host computer and generate the first control signal.

In some embodiments, a receiving link may include the signal acquisition module 110, the signal matching module 120, and the analog-to-digital converter 130. In some embodiments of the present disclosure, the magnetic resonance signal carrying the specific nuclide information may be received through the receiving link, and signal demodulation may be performed in the digital domain to generate the K-space data corresponding to the magnetic resonance signal, so that the receiving link constructed based on the analog-to-digital converter 130 may be relatively short, thereby reducing an overall volume of the signal acquisition device 100 and improving the integration degree.

In addition, the signal matching module 120 may select a specific narrowband signal for transmission under broadband through a cooperation of the adjustable capacitor unit and the radio frequency transformer, which may realize broadband tuning and matching with a simple architecture. At the same time, the signal matching module 120 may also slow down the intrusion of radio frequency interference through a narrow receiving frequency band, so that the signal acquisition device 100 can work stably.

Furthermore, when it is necessary to obtain magnetic resonance signals corresponding to other nuclide information, the signal acquisition device 100 may not need to replace an entire receiving link, and may replace the signal acquisition module and adjust the capacitance value of the adjustable capacitance unit, so that the adjustable capacitor unit may cooperate with the radio frequency transformer to complete the adjustment of the receiving frequency band, thereby achieving a purpose of receiving a plurality of different magnetic resonance signals using the same link architecture.

The signal acquisition module 110 may include a circuit structure for receiving magnetic resonance signals. In some embodiments, the signal acquisition module 110 may acquire one or more magnetic resonance signals carrying nuclide information, and the nuclide information may include a resonance frequency (i.e., a nuclide frequency) corresponding to the nuclide, a signal amplitude, etc. In some embodiments, the signal acquisition module 110 may obtain a magnetic resonance signal of a specific nuclide frequency. For more descriptions of the nuclide, please refer to relevant descriptions in FIG. 2 above, which will not be repeated here.

In some embodiments, the signal acquisition module 110 may include a plurality of radio frequency receiving units, and each radio frequency receiving unit may include a radio frequency receiving coil and an anti-aliasing filter. The radio frequency receiving coil may be configured to receive a magnetic resonance signal of a specific nuclide frequency, and the anti-aliasing filter may be configured to filter the magnetic resonance signal of the specific nuclide frequency.

A radio frequency receiving unit may be configured to receive a magnetic resonance signal of a specific nuclide frequency. Radio frequency receiving units with different parameters may be used for receiving magnetic resonance signals of different nuclide frequencies, and each radio frequency receiving unit may correspond to a magnetic resonance signal of a specific nuclide frequency. For example, for a radio frequency receiving unit used to receive the 1H nuclide frequency, a signal receiving frequency of the radio frequency receiving coil and a passband frequency range of the anti-aliasing filter in the radio frequency receiving unit may be set according to the 1H nuclide frequency.

The radio frequency receiving coil, also known as a local coil or a probe, may receive a magnetic resonance signal corresponding to a specific nuclide frequency by inducing the radiation of electromagnetic waves of the specific nuclide frequency. In some embodiments, the signal receiving frequency of the radio frequency receiving coil may correspond to a specific nuclide frequency of a magnetic resonance signal to be received.

An anti-aliasing filter (AAF) may include a low-pass filter, which may be used to reduce an aliasing frequency component in a signal, such as to suppress mirror image noise in a magnetic resonance signal. In some embodiments, the anti-aliasing filter may be constructed by using resistor-capacitor (RC) components or inductor-capacitor (LC) components. In some embodiments, the passband frequency range of the anti-aliasing filter may be set according to a sampling rate of the analog-to-digital converter 130 (i.e., a frequency of a clock signal described below) and the specific nuclide frequency, so as to avoid deterioration of a signal-to-noise ratio of the signal acquisition device 100 due to mirror image noise aliasing. For example, the passband frequency range of the anti-aliasing filter may include the nuclide frequency corresponding to the radio frequency receiving unit but not include the sampling rate of the analog-to-digital converter 130.

In some embodiments, the anti-aliasing filter may filter the magnetic resonance signal of the specific nuclide frequency, allow the magnetic resonance signal in the passband frequency range to pass, and suppress the mirror image noise in a stopband frequency range, which can obtain the magnetic resonance signal carrying the specific nuclide information. An exemplary signal acquisition device 100 is provided below, and more descriptions of the radio frequency receiving unit are described in detail.

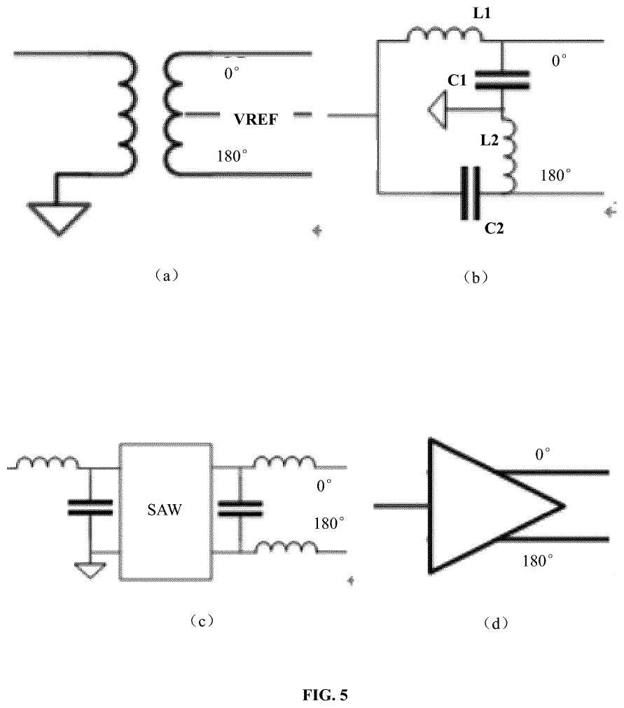

FIG. 4 is a schematic diagram illustrating a structure of the signal acquisition device 100 according to some embodiments of the present disclosure. As shown in FIG. 4, the signal acquisition module 110 may include one or more radio frequency receiving units (denoted as circles in FIG. 4), wherein the anti-aliasing filter (denoted as AAF in FIG. 4) may be set close to the radio frequency receiving coil. Each radio frequency receiving unit may be configured to receive and output a magnetic resonance signal of a specific nuclide frequency. The magnetic resonance signal may carry the specific nuclide information.

, Compared with a traditional signal acquisition device, the anti-aliasing filter in some embodiments of the present disclosure may be set close to the radio frequency receiving coil, which may make the receiving link move forward as a whole and be closer to the radio frequency receiving coil, and suppress the mirror image noise at a source of signal reception so that the radio frequency interconnection cables from the radio frequency receiving coil to the receiving link can be reduced, and the circuit structure can be optimized when the signal-to-noise ratio of the signal acquisition device 100 is optimized.

In some embodiments, the signal acquisition device 100 further includes a gain amplifier (e.g., a VGA as shown in FIG. 4), which is located between the signal acquisition module 110 and the signal matching module 120. The gain amplifier may be configured to amplify the magnetic resonance signal according to a second control signal.

The gain amplifier may be a circuit structure that amplifies the signal amplitude. In some embodiments, the gain amplifier may be configured to amplify the magnetic resonance signal transmitted from the signal acquisition module 110. In some embodiments, the gain amplifier may be a fixed gain amplifier or a variable gain amplifier (VGA), or other devices capable of amplifying signals. In some embodiments, when the gain amplifier is a fixed gain amplifier, a fixed gain amplifier with an appropriate amplification time may be selected according to a signal amplitude of a magnetic resonance signal to be obtained. For example, a fixed gain amplifier with a large range of amplification times may be selected for signal amplification in a magnetic resonance spectroscopy device.

In some embodiments, when the gain amplifier is a variable gain amplifier, the amplification time of the variable gain amplifier may be set according to the signal amplitude of the magnetic resonance signal. Exemplarily, the larger the signal amplitude, the smaller the amplification time of the gain amplifier; conversely, the smaller the signal amplitude, the larger the amplification time of the gain amplifier, so as to realize the adjustment control of the magnetic resonance signal. In some embodiments, a second control signal may be obtained from the control module 140, and the second control signal may be configured to adjust the amplification time of the variable gain amplifier. For more descriptions of the second control signal, please refer to the content of the control module 140 described below, which will not be repeated here. More descriptions of the variable gain amplifier is described in detail below in conjunction with the signal acquisition device 100 shown in FIG. 4.

In some embodiments, as shown in FIG. 4, a variable gain amplifier (denoted as VGA in FIG. 4) may be disposed between the signal acquisition module 110 and the signal matching module 120 to amplify the magnetic resonance signal output by the anti-aliasing filter, so that the signal amplitude of the signal input into the matching module 120 may be stable.

In some embodiments of the present disclosure, the variable gain amplifier is used to process signals of different amplitudes. The variable gain amplifier may have a high amplification time when a signal with a low amplitude is input and a low amplification time when a signal with a high amplitude is input, so that the amplitude of the signal input into the matching module 120 may be stable, so as to achieve the dynamic range of the analog-to-digital converter.

The signal matching module 120 may be a circuit structure that uses differential transformation to perform signal processing. In some embodiments, the signal matching module 120 may convert an input single-ended signal (e.g., the above-mentioned magnetic resonance signal) into an analog differential signal, so that the analog-to-digital converter 130 may perform subsequent signal processing. In some embodiments, the signal matching module 120 may be constructed based on architectures such as a high-speed operational amplifier, a radio frequency transformer, and an inductor-capacitor (LC) component. More descriptions of the signal matching module 120 will be described in detail below by taking the radio frequency transformer as an example.

In some embodiments, the signal matching module 120 may include an adjustable capacitance unit and a radio frequency transformer. The adjustable capacitance unit may be configured to adjust a capacitance value according to a first control signal to cooperate with the radio frequency transformer to receive the magnetic resonance signal corresponding to the specific nuclide information and convert the magnetic resonance signal into the analog differential signal.

The radio frequency transformer may be a transformer that works in a radio frequency range, which may be configured to realize the transmission of radio frequency energy and convert a single-ended signal into the analog differential signal. In some embodiments, the radio frequency transformer may include one or more balun transformers to match an analog differential input interface of the analog-to-digital converter. Furthermore, when applied in the field of magnetic resonance, the receiving link of the signal acquisition device 100 may need to be non-magnetized, and the balun transformer may be a non-magnetic core balun transformer with an air-core or ceramic-core, and the type of the balun transformer may be selected according to actual application scenarios.

In some embodiments, the radio frequency transformer may include one or more stages of non-magnetic core balun transformers connected in series. In some embodiments, as shown in FIG. 4, the radio frequency transformer may include a non-magnetic core balun transformer T1 and a non-magnetic core balun transformer T2. A secondary side of the non-magnetic core balun transformer T1 may be connected to a primary side of the non-magnetic core balun transformer T2. A primary side of the non-magnetic core balun transformer T1 may receive the magnetic resonance signal, and a secondary side of the non-magnetic core balun transformer T2 may output the analog differential signal, realizing a concatenation of the non-magnetic core balun transformers. Using stages of balun transformers may increase an output voltage of the radio frequency transformer and improve amplitude-phase balance characteristics of positive and negative terminal signals of the analog differential signal, thereby increasing the gain of the receiving link. At the same time, a suppression degree of signals outside the passband frequency range (that is, out-of-band suppression) can be optimized to improve the effect of the anti-aliasing filtering.

It should be noted that since the non-magnetic core balun transformer(s) do not have a magnetic core, it may only work in a narrow frequency range. But the non-magnetic core balun transformer(s) may cooperate with the adjustable capacitor unit, and make the radio frequency transformer select a specific narrowband signal for transmission under the broadband by adjusting the capacitance value of the adjustable capacitor unit, so that certain broadband characteristics (e.g., low-loss signal transmission, broadband resonance matching) may be maintained within a limited frequency range. The structure of the radio frequency transformer is simple, and at the same time, the intrusion of radio frequency interference may be slowed down through a relatively narrow receiving frequency band, so that the signal acquisition device 100 can work stably.

In some optional embodiments, the radio frequency transformer may also choose other forms of balun transformers, so as to realize the function of matching the analog differential input interface of the analog-to-digital converter. In some embodiments, an appropriate radio frequency transformer may be selected and set in the receiving link according to different application scenarios and requirements, so as to improve the overall performance of the receiving link. In some optional embodiments, the radio frequency transformer may include one or a combination of a transformer balun, an inductor-capacitor (LC) balun, a surface-acoustic balun, or a differential operational amplifier. Several exemplary baluns are given below to describe the specific implementation of the baluns in detail.

FIG. 5 is a schematic diagram illustrating exemplary structures of a radio frequency transformer according to some embodiments of the present disclosure. The radio frequency transformer may include one or more of a transformer balun as shown in FIG. 5 (a), an inductor-capacitor (LC) balun as shown in FIG. 5 (b), a surface-acoustic balun as shown in FIG. 5 (c), and a differential operational amplifier as shown in FIG. 5 (d).

The transformer balun may be a type of balun constructed based on a transformer, which has RF emitting and/or receiving functions. In some embodiments, as shown in FIG. 5 (a), one side of the transformer balun may be grounded and the other side may be floated for differential. For example, a primary side of the transformer balun may be connected to the variable capacitance unit, and a secondary side of the transformer balun may be connected to the analog-to-digital converter to output the analog differential signal. By setting the transformer balun in the receiving link provided in the present disclosure, the bandwidth of the receiving link can be increased, and a magnetic resonance signal with a uniform phase and little interference can be obtained.

The inductor-capacitor (LC) balun may be a balun that shifts a phase of a branch through inductor and/or capacitor. In some embodiments, as shown in FIG. 5 (b), the LC balun may unitize a series capacitor and a parallel inductor in the branch to make an electric current of the branch have a leading phase, and utilize a parallel capacitor and a series inductor in another branch to make the voltage of the other branch have a delayed phase, thereby realizing the output of the differential signal. Exemplarily, as shown in FIG. 5 (b), an end of a capacitor C2 is connected to an end of an inductor L1, which may be configured to receive an input signal. The other end of the inductor L1 and the other end of the capacitor C2 may be respectively configured as two output terminals for outputting the differential signal, thereby forming two branches. The first branch is provided with the series inductor L1 and a parallel capacitor C1 (one end of the capacitor C1 is connected to the output terminal of the first branch, and the other end of the capacitor C1 is grounded), which may make the electric current of the first branch has a leading phase. The second branch is provided with the series capacitor C2 and a parallel inductance L2 (one end of the inductance L2 is connected to the output terminal of the second branch, and the other end of the inductance L2 is grounded), which may make the phase of the voltage of the second branch lag.

The surface-acoustic balun may have functions of surface-acoustic filtering and converting a single-ended signal to a differential signal. In some embodiments, as shown in FIG. 5 (c), the surface-acoustic balun may include a surface acoustic wave filter (SAW) and a plurality of inductors and capacitors. An input terminal of the SAW may be connected to capacitors in parallel and an output terminal of the SAW may be connected to a plurality of inductors in series, which may realize the output of the differential signal and realize ultra-narrowband filtering using the SAW at the same time. The surface-acoustic balun may be set in the receiving link provided in the present disclosure while realizing the function of converting a single-ended signal to a differential signal, the radio frequency transformer may also have a function of ultra-narrowband filtering, thereby reducing the noise introduced in the receiving link.

In some embodiments, the differential operational amplifier may also realize the function of converting a single-ended signal to a differential signal of the radio frequency transformer. Exemplarily, as shown in FIG. 5 (d), an input terminal of the differential operational amplifier may receive a single-ended signal (e.g., the aforementioned magnetic resonance signal), and the output terminal may respectively output differential signals with a phase difference of 180° (e.g., the aforementioned analog differential signal). Setting the differential operational amplifier in the receiving link provided in the present disclosure can widen the bandwidth of the receiving link and provide certain gain compensation.

The adjustable capacitor unit may include one or more variable capacitors (e.g., varactor diodes) and other capacitors. In some embodiments, the adjustable capacitance unit may include one or more variable capacitors and one or more fixed capacitors. The variable capacitors and the fixed capacitors may be connected in series or parallel to form the adjustable capacitance unit. In some embodiments, the adjustable capacitor unit may be disposed at the input terminal of the radio frequency transformer, for example, the adjustable capacitor unit may be disposed at the primary side of the balun transformer.

In some embodiments, the adjustable capacitance unit may change an applied voltage of the variable capacitor according to a first control signal received from a drive circuit, so as to adjust its own capacitance value and cooperate with the radio frequency transformer to complete the adjustment of the receiving frequency band and receive the magnetic resonance signal corresponding to the specific nuclide information. Correspondingly, the control module may send a first control signal to the adjustable capacitor unit through the drive circuit according to an instruction of a host computer, so that the adjustable capacitor unit may cooperate with the radio frequency transformer to complete the adjustment of the receiving frequency band. For more descriptions of the drive circuit and the control module, please refer to related contents of the control module 140 described below.

In some embodiments, the capacitance value of the adjustable capacitance unit may affect a tuning range of the radio frequency transformer, that is, the receiving frequency band of receiving signals. Correspondingly, the control module 140 may determine the tuning range of the radio frequency transformer to be adjusted and the capacitance value of the adjustable capacitor unit according to the nuclide frequency corresponding to the magnetic resonance signal to be obtained. Exemplarily, the capacitance value of the adjustable capacitor unit and the tuning range of the radio frequency transformer may be adjusted so that the nuclide frequency corresponding to the magnetic resonance signal is located at a best matching point of the adjustable capacitor and the balun transformer, thereby realizing the broadband resonance matching. For the signal of the specific nuclide, the tuning may also act as a bandpass filter and replace the anti-aliasing filter connected to the analog-to-digital converter 130.

In some embodiments of the present disclosure, when the capacitance value is properly adjusted (for example, the nuclide frequency is located at the best matching point between the adjustable capacitor and the balun transformer), the radio frequency transformer may select a specific narrowband signal for transmission under the broadband, which may realize an optimum broadband resonance matching and reduce an energy loss during the transmission, so that the radio frequency energy of signals may be transmitted to the analog-to-digital converter 130 as much as possible. Exemplarily, the analog differential signal received at an analog input terminal of the analog-to-digital converter 130 may maintain a maximum peak value of an alternating current (AC) voltage peak.

Furthermore, when it is necessary to obtain a magnetic resonance signal corresponding to other nuclide information, the signal acquisition device may not need to replace the entire receiving link, and may replace the signal acquisition module and adjust the capacitance value of the adjustable capacitance unit, so that the adjustable capacitor unit may cooperate with the radio frequency transformer to complete the adjustment of the receiving frequency band, thereby achieving a purpose of receiving a plurality of different magnetic resonance signals using the same link architecture.

It should be noted that the frequency band of an electromagnetic induction signal having the frequency of the specific nuclide is narrow and close to a single frequency point. Therefore, the signal acquisition device 100 may ensure that the frequency of the specific nuclide is just located at the best matching point between the adjustable capacitor and the balun transformer through a precise automatic tuning and calibration workflow in a pre-scanning preparation stage. Furthermore, a minimum link attenuation can be guaranteed and the energy loss during the transmission can be reduced.

In some embodiments, the adjustable capacitance unit may include one or more varactor components. Each varactor component may include two varactor diodes connected in parallel or series, and the two varactor diodes may have opposite direct current (DC) bias directions. In some embodiments, alternating current (AC) directions of the two varactor diodes may be the same.

A varactor component may be a combination of two varactor diodes, and a capacitance of the varactor diodes may change with a change in the applied voltage. In some embodiments, the adjustable capacitance unit may change the capacitance value of the adjustable capacitance unit by adjusting the applied voltage of the two varactor diodes in the varactor component. In some embodiments, the DC bias directions of the two varactor diodes may be opposite but the AC directions of the two varactor diodes may be the same.

Two exemplary adjustable capacitor units are provided below to describe the specific structure of the varactor component in detail.

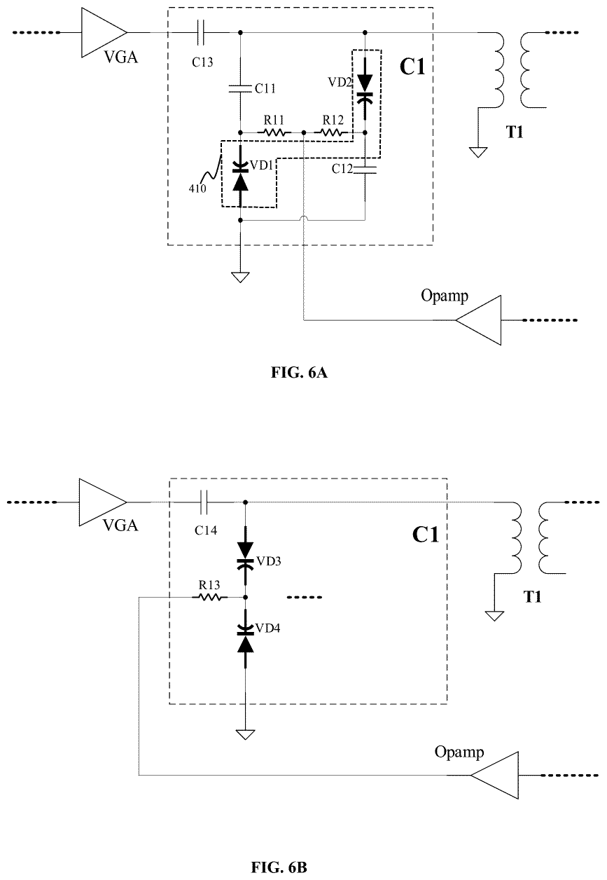

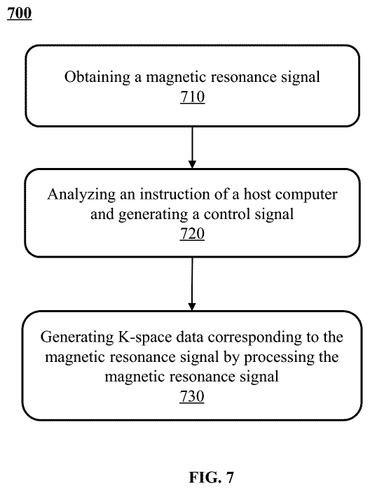

FIG. 6A is a schematic diagram illustrating a structure of a parallel adjustable capacitor unit according to some embodiments of the present disclosure. In some embodiments, as shown in FIG. 6A, an adjustable capacitance unit C1 may include a varactor component 410, and the varactor component 410 may include varactor diodes VD1 and VD2 connected in parallel. A cathode of the varactor diode VD1 is connected to an anode of the varactor diode VD2 through a capacitor C11. A cathode of the varactor diode VD2 is connected to an anode of the varactor diode VD2 through a capacitor C12. The cathode of the varactor diode VD1 is connected to the cathode of the varactor diode VD2 through a resistor R11 and a resistor R12 connected in series. The DC bias directions of the varactor diodes VD1 and VD2 may be opposite but the AC directions thereof may be the same.

In some embodiments, as shown in FIG. 6A, a connection point of the resistor R11 and the resistor R12 may be connected to an output terminal of a drive amplifier (also referred to as an operational amplifier (Opamp)), and receive a first control signal from the control module 140. A connection point between the cathode of the varactor diode VD1 and the anode of the varactor diode VD2 may be also connected to the output terminal of the VGA through a capacitor C13, and the connection point may be also connected to an input terminal of a primary side of a non-magnetic core balun transformer T1. Both the anode of the varactor diode VD1 and an output terminal of the primary side of the non-magnetic core balun transformer T1 are grounded.

In some embodiments of the present disclosure, when the VGA outputs a magnetic resonance signal with a large amplitude, the parallel structure of the varactor component 410 in the adjustable capacitance unit C1 shown in FIG. 6A may reduce a non-linear distortion produced by the varactor diodes VD1 and VD2, which can optimize the quality of the magnetic resonance signal.

FIG. 6B is a schematic diagram illustrating a structure of a series adjustable capacitor unit according to some embodiments of the present disclosure. In some embodiments, as shown in FIG. 6B, an adjustable capacitance unit C1 may include a varactor component 420, and the varactor component 420 may include varactor diodes VD3 and VD4 connected in series. A cathode of the varactor diode VD3 is connected to a cathode of the varactor diode VD4. DC bias directions of the varactor diodes VD3 and VD4 may be opposite but AC directions of the varactor diodes VD3 and VD4 may be the same.

In some embodiments, an anode of the varactor diode VD4 is grounded, and an anode of the varactor diode VD3 is connected to the output terminal of the VGA through a capacitor C14. The anode of the varactor diode VD3 is also connected to an input terminal of the primary side of the non-magnetic core balun transformer T1. A connection point between the cathode of the varactor diode VD3 and the cathode of the varactor diode VD4 is connected to the output terminal of an Opamp through a resistor R13 to receive a first control signal from the control module 140.

In some embodiments of the present disclosure, when the VGA outputs a magnetic resonance signal with a large amplitude, a series structure of the variable capacitance component 420 in the adjustable capacitance unit C1 shown in FIG. 6B may reduce a non-linear distortion produced by the varactor diodes VD3 and VD4, which can optimize the quality of the magnetic resonance signal. However, compared with the parallel structure of the variable capacitance component 410 in the adjustable capacitance unit C1 shown in FIG. 6A, the tuning range of the radio frequency transformer corresponding to the series structure is small, and the adjustment degree is low.

In some optional embodiments, the two varactor diodes in the varactor component may also be disposed in an asymmetric structure. In some optional embodiments, the two varactor diodes in the varactor component may be disposed symmetrically. For example, the two varactor diodes shown in FIGS. 6A-6B may be symmetrically disposed in the circuit structure.

In some embodiments, the adjustable capacitance unit may further include a DC blocking module and/or an AC blocking module. The DC blocking module may be configured to isolate DC signals, and the AC blocking module may be configured to isolate AC signals. In some embodiments, the DC blocking module may include one or more capacitors. Exemplarily, as shown in FIG. 6A above, the DC blocking module may include the capacitors C11 to C13. As shown in FIG. 6B above, the DC blocking module may include the capacitor C14. Further, the DC blocking module may include a DC blocking capacitor (e.g., the capacitor C13 in FIG. 6A and the capacitor C14 in FIG. 6B) connected to the VGA in series. The DC blocking capacitor may be configured to prevent the bias voltage of the VGA from being directly grounded by the source of the balun transformer T1.

In some embodiments, the AC blocking module may include one or more resistors or inductors. Exemplarily, as shown in FIG. 6A above, the AC blocking module may include the resistor R11 and the resistor R12. As shown in FIG. 6B above, the AC blocking module may include the resistor R13. Further, the resistors of the AC blocking module may be connected to the Opamp in series, so as to realize DC conduction and AC isolation to prevent the magnetic resonance signal output by the VGA from breaking down a low-pass filter and/or the drive amplifier.

Since the reverse current of a varactor diode is very small, in some embodiments, the adjustable capacitance unit may set a large resistor connected with the varactor diode in series, thereby isolating the magnetic resonance signal output from the VGA and transmitting the first control signal transmitted by the Opamp.

It should be noted that since the varactor diodes (that is, the adjustable capacitance unit) have nonlinear characteristics, when the signal acquisition device 100 retains the nonlinear amplitude-phase distortion caused by the adjustable capacitance unit, the nonlinear characteristic of the varactor diodes may cause a signal attenuation (e.g., an attenuation of the amplitude of the signal), so that the signal amplitude range may fall within an input amplitude range of the analog-to-digital converter 130, thereby achieving amplitude compression. In some embodiments, the nonlinear amplitude-phase distortion of the signal generated by the adjustable capacitor unit may be compensated by an amplitude-phase nonlinear distortion compensation module (A-P-Correct) of the control module 140 to restore the signal, which can improve the receiving dynamic range of the signal amplitude of the receiving link. Furthermore, most part of odd harmonics generated by nonlinear distortion characteristics may also be filtered out by the characteristics of the radio frequency transformer. For more descriptions of the compensation of the nonlinear amplitude-phase distortion, please refer to related contents in the control module 140 described below, which will not be repeated here.

In some optional embodiments, the two varactor diodes in a varactor component may be replaced with a DC blocking capacitor module, so as to retain the nonlinear distortion characteristics. Exemplarily, as shown in FIG. 6A, the varactor diode VD1, capacitor C11, and resistor R11 may be removed, or the varactor diode VD2, capacitor C13, and resistor R12 may be removed. As shown in FIG. 6B, the capacitor C14 may be used to replace the varactor diode VD3 or the varactor diode VD4.

In some optional embodiments, the signal acquisition device 100 may utilize a combination of two varactor diodes of different types, and retain the nonlinear distortion characteristics through differences in parameter indexes of the two varactor diodes. In some optional embodiments, the signal acquisition device 100 may include an even number of varactor diodes and be connected in parallel with one or more varactor diodes based on a symmetrical topology of a parallel structure or a series structure, so as to retain the nonlinear distortion characteristics of the adjustable capacitance unit.

In some optional embodiments, the adjustable capacitance unit may be realized by using other devices with adjustable capacitance, such as a digitally controlled variable capacitor and an optional capacitor group connected in parallel. The digitally controlled variable capacitor may adjust the capacitance value according to a control instruction of the control module. Compared with the optional capacitor group connected in parallel, the capacitance value of the digitally controlled variable capacitor is relatively stable, and it may be regarded as an ideal capacitor. The optional capacitor group connected in parallel may be controlled by a switch, so as to adjust the capacitance value of the adjustable capacitor unit.

In some optional embodiments, the adjustable capacitance unit may include a plurality of capacitors connected in parallel and at least one switch, and the at least one switch is configured to control the status of the plurality of capacitors connected in parallel. In some embodiments, the capacitance values of the plurality of capacitors may be fixed, the capacitance values of different parallel branches may be different. Switches may be set between different branches, so as to control a connection relationship of capacitors in the plurality of parallel branches by turning on and off the switches and realize the adjustment of the capacitance value of the overall adjustable capacitor unit. Exemplarily, the adjustable capacitance unit may include a first parallel branch and a second parallel branch. A switch 1 may control the status of the first parallel branch, and switch 2 may control the status of the second parallel branch. When the switch 1 is turned on and the switch 2 is turned off, only the first parallel branch may be connected, and the capacitance value of the adjustable capacitor unit may be the capacitance value of the first parallel branch. When the switch 1 is turned off and the switch 2 is turned on, only the second parallel branch may be connected, and the capacitance value of the adjustable capacitor unit may be the capacitance value of the second parallel branch. When both switch 1 and switch 2 are turned on, the first parallel branch and the second parallel branch may be connected in parallel, and the capacitance value of the adjustable capacitor unit may be a total capacitance value of the first parallel branch and the second parallel branch. Further, the adjustable capacitance unit may further include a capacitor array composed of a plurality of capacitors. At least one switch may control the status of different capacitors in the capacitor array.

In some embodiments of the present disclosure, by adjusting the resistance value of the adjustable capacitor unit, the adjustable capacitor unit may cooperate with peripheral devices (such as the radio frequency transformer, the variable gain amplifier, etc.), so that a broadband reception of a multi-core frequency band can be realized through the same link architecture, and the receiving dynamic range of the signal amplitude of the receiving link can be improved through the nonlinear distortion. At the same time, the circuit structure is simple and the integration degree is high, which facilitates the miniaturization of the signal acquisition device 100.

Moreover, compared to a traditional manner of using a high-speed operational amplifier to convert the single-ended signal into the analog differential signal, the signal matching module 120 in some embodiments of the present disclosure may make the radio frequency transformer realize the broadband resonant matching through the cooperation of the radio frequency transformer and the adjustable capacitance unit, so that the signal matching module 120 may have certain anti-aliasing characteristics, which can indirectly reduce design requirements for the anti-aliasing filter in the signal acquisition module 110 and simplify the circuit of the signal acquisition module 110.

At the same time, compared with a traditional single-ended-to-differential balun module built by discrete inductors and capacitors, the cooperation of the radio frequency transformer and the adjustable capacitor unit in some embodiments of the present disclosure may make the signal matching module 120 have a better out-of-band component suppression effect, in-band flatness, and amplitude-phase balance characteristics of converting the single-ended signal to the differential signal. The circuit architecture is relatively simple, and the integration degree is high, which facilitates the miniaturization of the signal acquisition device 100.

The analog-to-digital converter 130 (ADC) may be an electronic device that converts an input analog signal into a signal that is discrete in a time domain and digitized in amplitude according to a sampling rate (such as a frequency of a clock signal described below). In some embodiments, the analog-to-digital converter 130 may be a high-speed analog-to-digital converter 130 with a high sampling rate, so as to facilitate the design of the anti-aliasing filter in the signal acquisition module 110 and to optimize the anti-aliasing characteristics of the adjustable capacitor unit and the radio frequency transformer. Exemplarily, the sampling rate of the high-speed analog-to-digital converter 130 may be 100 MSPS, 120 MSPS, etc.

In some embodiments, the analog-to-digital converter 130 may be disposed between the signal matching module 120 and the control module 140, and the analog-to-digital converter 130 may be configured to convert the analog differential signal into a digital signal. Exemplarily, as shown in FIG. 4, an analog-to-digital converter may be set at the output terminal of the balun transformer T2. Further, the analog-to-digital converter 130 may sample the analog differential signal according to one or more clock signals to obtain the digital signal. The clock signal(s) may be generated from a clock generation module. In some embodiments, the analog-to-digital converter 130 may set the sampling rate based on frequencies of one or more clock signals. Exemplarily, as shown in FIG. 4, the analog-to-digital converter may receive and select the frequency of a clock signal CLK1 or the frequency of a clock signal CLK2 for sampling. More descriptions of the clock signal can be found in relevant descriptions regarding the clock generation module below, which will not be repeated here.

In some embodiments, an analog input terminal of the analog-to-digital converter 130 may adopt a high-speed differential interface, and a digital output terminal of the analog-to-digital converter 130 may adopt a high-speed serial interface. The analog-to-digital converter 130 may convert parallel digital data corresponding to a plurality of data processing paths through data packaging and a serial-parallel protocol, and then output differential high-speed digital signals through one or a small count of high-speed serial interfaces. In some embodiments, the analog-to-digital converter 130 may select a corresponding data processing path for digital output according to the control module 140. Correspondingly, the control module 140 may also perform subsequent digital signal processing on a selected data processing path. In some embodiments of the present disclosure, the analog-to-digital converter 130 may utilize the high-speed serial interface and a bus output, so that a switch module may complete a multi-path selection function for the differential high-speed digital signal. Compared with a parallel bus, the high-speed serial interface in some embodiments of the present disclosure may have fewer lines, thereby saving the resources of the control module 140 and a circuit board, and improving the integration degree, which facilitates the miniaturization of the signal acquisition device 100.

In some embodiments, the signal acquisition device 100 may also include a clock generation module. The clock generation module may be disposed between the control module 140 and the analog-to-digital converter 130, which may be configured to generate a clock signal according to an instruction of the host computer. The analog-to-digital converter 130 may sample the analog differential signal according to the clock signal to obtain the digital signal.

The clock generation module may be an electronic device that outputs a unified and integrated clock signal to enable other electronic devices to work normally. In some embodiments, the clock generation module may output a signal of a specific frequency based on a phase-locked loop in the control module 140. The phase-locked loop may tune a voltage-controlled oscillator of the clock generation module using the voltage generated by phase synchronization to generate a signal of a target frequency.

In some embodiments, the clock generation module may generate a clock signal corresponding to the instruction of the host computer according to the voltage from the control module 140, and the frequency of the clock signal may correspond to the instruction of the host computer. Further, the clock generation module may provide one or more clock signals, and the frequencies of different clock signals may be different. Exemplarily, as shown in FIG. 4, the PLL may be used as the clock generation module to provide a clock signal CLK1 or a clock signal CLK2 for the analog-to-digital converter, and the PLL may also provide the control module 140 with the clock signal CLK1, the clock signal CLK2, and a clock signal CLK3.

In a process for collecting signals, mirror image frequency interference often occurs. If the difference between the nuclide frequency and the mirror image frequency of the magnetic resonance signal to be collected is too small, the analog-to-digital converter 130 may be easily aliased by mirror image noise during sampling. The anti-aliasing filter may be difficult to design, which may affect the quality of signal acquisition. The mirror image frequency may be several times half the sampling rate of the analog-to-digital converter 130 generally. Exemplarily, it may be assumed that the sampling rate of the analog-to-digital converter 130 is 200 MSPS, and correspondingly, the mirror image frequency may be 50 MHZ, 100 MHZ, 200 MHZ, 300 MHZ, or the like. If the nuclide frequency of the magnetic resonance signal to be collected is 98 MHZ, the difference between the nuclide frequency of 98 MHz and the image frequency of 100 MHz is less than 5% of the nuclide frequency, which may easily affect the quality of signal acquisition.

In order to avoid the mirror image frequency interference, in some embodiments, the control module 140 may control the clock generation module to output a clock signal (e.g., the clock signal CLK1 and CLK2) corresponding to the nuclide frequency according to the nuclide frequency required in the instruction of the host computer. In some embodiments, the difference between the nuclide frequency of the magnetic resonance signal and a frequency of any times half the frequency of the clock signal may be within a preset difference range. Further, the preset difference range may be 5% of the nuclide frequency. The analog-to-digital converter 130 may determine the sampling rate according to the frequency of the clock signal. The unit of the frequency of the clock signal is different from the unit of the sampling rate, and their values are the same. Exemplarily, assuming that the nuclide frequency of the magnetic resonance signal to be collected is 200 MHz and the frequency of the clock signal may be 120 MHz, then the sampling rate of the analog-to-digital converter 130 may be 120 MSPS, and the frequency of any times half the frequency of the clock signal may be 60n MHz, where n is a positive integer greater than or equal to 1. When n=3, the triple frequency of half the frequency of the clock signal is 180 MHZ, which is closest to the nuclide frequency. The difference between 180 MHz and the nuclide frequency of 200 MHz is 20 MHZ, and the difference is greater than the mirror image frequency or 5% of the nuclide frequency. Under the action of the anti-aliasing filter, setting the working frequency band of the analog-to-digital converter 130 near 200 MHz may avoid the aliasing of the mirror image noise with any image frequency, and ensure the stability of the signal quality (signal-to-noise ratio) of the signal acquisition device 100.

In some optional embodiments, the control module 140 may also control the clock generation module to output a clock signal selected from preset clock signals. Exemplarily, for a medical device with a B0 field strength of 9.4 T, the control module 140 may control the clock generation module to output a clock signal CLK1 with a frequency of 100 MHZ, or to output a clock signal CLK2 with a frequency of 120 MHZ. An exemplary correspondence table between the nuclide frequency of the magnetic resonance signal and the sampling rate of the analog-to-digital converter 130 is provided below.

TABLE 1

| Nuclide | ¹H | ²H | ¹⁹F | ³¹P | ¹²⁹Xe | ²³Na | ¹³C | ¹⁷O | ¹⁵N |
|---|---|---|---|---|---|---|---|---|---|
| Nuclide | 400 | 61.4 | 376.3 | 161.9 | 110.6 | 105.8 | 100.6 | 54.2 | 40.5 |
| Fre- | | | | | | | | | |
| quency | | | | | | | | | |
| (MHz) | | | | | | | | | |
| sampl- | 120 | 100 | 100, | 120, | 100, | 120, | 120 | 120, | 120, |
| ing rate | | | 120 | 100 | 120 | 100 | | 100 | 100 |
| (MSPS) | | | | | | | | | |

Table 1 is a correspondence table between available nuclide frequencies and the sampling rates of the analog-to-digital converter 130 when the B0 field strength is 9.4 T. As shown in Table 1, for the medical device with the B0 field strength of 9.4 T, the frequency of the clock signal output by the clock generation module is 100 MHz or 120 MHz, which may prevent the signal acquisition device 100 from being interfered by the mirror image noise in most multi-core frequency bands. In addition, the anti-aliasing filter may also be constructed through conventional LC (inductor-capacitor) components in the signal acquisition module 110 to further reduce the interference of the mirror image noise.

In some embodiments, a clock signal (such as the clock signals CLK1 and CLK2) may be configured to provide a reference for the control module 140 to select the receiving path, and the clock signal (such as the clock signal CLK3) may also be configured to provide a carrier wave for the control module 140 to output the control signal (e.g., the first control signal, the second control signal, and the third control signal). For more descriptions of the clock signal in the control module 140, please refer to relevant descriptions in the control module 140 below, which will not be repeated here.

In some embodiments of the present disclosure, the clock generation module may output a clock signal with an appropriate frequency, and adjust the sampling rate of the analog-to-digital converter 130, thereby improving the problem that the mirror image frequency is too close to the nuclide frequency. While reducing the mirror image noise of the signal acquisition device 100, it is also convenient to design the anti-aliasing filter and improve the quality of signal acquisition.

The control module 140 may be a circuit unit having data processing and control functions. In some embodiments, the control module 140 may be an integrated circuit ASIC, a field programmable gate array (FPGA), a complex programmable logic device (CPLD), a microcontroller unit (MCU), a central processing unit (CPU), a digital signal processor (DSP), a graphics processing unit (GPU), or other circuit modules. The control module 140 may include functional units such as logic gate circuits, registers, hard-core multipliers, random access memories (RAMs), phase-locked loops, and high-speed serial-to-parallel conversions.

In some embodiments, the control module 140 may process the digital signal output by the analog-to-digital converter 130, and output K-space data corresponding to the nuclide information to the host computer. The K-space data may be a kind of image data, and the host computer (e.g., the imaging device shown in FIG. 2) may use the K-space data to perform image reconstruction and output image information corresponding to the nuclide information.

In some embodiments, the control module 140 may include a plurality of data processing paths, and each data processing path may include a digital down-conversion (DDC) module, which may be configured to extract, filter, and demodulate the digital signal to obtain the digital output signal.

A data processing path may be a circuit for receiving and processing the digital signal from the analog-to-digital converter 130. For example, the data processing path may be a high-speed serial input of an FPGA. In some embodiments, each data processing path may process a digital signal corresponding to a nuclide frequency. In some embodiments, the DDC module may be a circuit module that performs frequency mixing in a digital field. For example, the DDC module may be configured to extract, filter, and demodulate the digital signal to obtain a digital output signal (such as the K-space data) corresponding to the nuclide frequency.

In some embodiments, the digital down-conversion modules in different data processing paths may have different downsampling rates. Exemplarily, as shown in FIG. 4, the control module 140 may include a digital down-conversion module DDC1 and a digital down-conversion module DDC2. The downsampling rate of the digital down-conversion module DDC1 may be k1, and the downsampling rate of the digital down-conversion module DDC2 may be k2.

In order to ensure that data rates of the K-space data corresponding to different data processing paths are the same, in some embodiments, the control module 140 may select a data processing path and determine the downsampling rate corresponding to the data processing path according to the sampling rate corresponding to the digital signal. The data rate of the selected data processing path may be a ratio of the sampling rate to the downsampling rate, which may be configured to reflect the difference between an amount of data after digital down-conversion processing and an amount of data in the digital signal. Exemplarily, if the sampling rate of the analog-to-digital converter 130 selects the clock signal CLK1, the digital down-conversion module DDC1 may be selected to complete downsampling with the downsampling rate of k1. If the sampling rate of the analog-to-digital converter 130 selects the clock signal CLK2, the digital down-conversion module DDC2 may be selected to complete downsampling with the downsampling rate of k2. Therefore, the data rates of K-space data obtained through different data processing paths are the same, i.e.,

$$\frac{CLK 1}{k 1} = \frac{CLK 2}{k 2} .$$

In this embodiment of the present disclosure, when it is necessary to obtain magnetic resonance signals corresponding to other nuclide information, the control module 140 may not need to replace the data processing path and may select the other one of the plurality of data processing paths to make the data rate of the K-space data remain unchanged, so that the same control module 140 may process a plurality of digital signals with different nuclide frequencies.

In some optional embodiments, the control module 140 may only include one data processing path, and the downsampling rate of the data processing path may correspond to the sampling rate of the analog-to-digital converter 130. Correspondingly, the clock generation module may be controlled to provide the analog-to-digital converter 130 with a clock signal corresponding to the nuclide frequency according to a required nuclide frequency in the instruction of the host computer. In this way, signal acquisition can be realized, and at the same time, the circuit structure of the control module 140 can be simplified, and the production cost can be reduced.

In some embodiments, the signal acquisition device 100 may further include a switch module, which may be disposed between the analog-to-digital converter 130 and the data processing paths. The switch module may be configured to select a data processing path corresponding to the clock signal, and connect the selected data processing path to the analog-to-digital converter 130.

The switch module may be a circuit module that opens a circuit, interrupts an electric current, or make the electric current flow to other circuits. In some embodiments, as shown in FIG. 4, the switch module may include a multi-path high-speed differential data switch (also referred to as a cross point switch (CPS)), which may be configured to change the data processing path connected to the analog-to-digital converter, that is, the data processing path where the digital down-conversion module DDC1 is located may be selected to be turned on, or the data processing path where the digital down-conversion module DDC2 is located may be selected to be turned on. In some embodiments, the switch module may switch between the plurality of data processing paths according to an instruction issued by the control module 140, and change the data processing path connected to the analog-to-digital converter 130.

In some embodiments, the control module 140 may also include a serial-parallel conversion module, which may be disposed between the switch module and the data processing path. The serial-parallel conversion module may be configured to convert serial data in the digital signal into parallel data, which may be convenient for digital down-conversion processing.

In some embodiments, as shown in FIG. 4, the control module 140 may further include a multi-path switch S2, and each switch in the multi-path switch may be disposed between the data processing path and the host computer. Similarly, the multi-path switch may be configured to select a data processing path corresponding to the clock signal and connect the data processing path to the host computer. In some embodiments, each switch may correspond to one high-speed differential data switch, and each switch and its corresponding high-speed differential data switch may correspond to the same data processing path. For more descriptions of the multi-path switch, please refer to relevant descriptions in the above-mentioned multi-path high-speed differential data switch, which will not be repeated here.

In some embodiments, as shown in FIG. 4, the control module 140 may include an analysis unit (denoted as Translate in FIG. 4), and the analysis unit may analyze the instruction of the host computer and generate a control signal (e.g., a first control signal, a second control signal, and a third control signal). The instruction of the host computer may be a Host instruction sent by a user through the host computer. In some embodiments, the instruction of the host computer may carry the nuclide information (e.g., the nuclide frequency, the name of the nuclide) of the magnetic resonance signal to be collected, and the instruction of the host computer may be used to direct the signal acquisition device 100 to collect the required magnetic resonance signal.

In some embodiments, the analysis unit may generate a control signal according to the nuclide information that needs to be received currently, so as to determine parameters of the circuit modules, functional units, or devices. Exemplarily, the analysis unit may determine a first control signal to control a counter module to adjust the capacitance value of the adjustable capacitance unit according to the nuclide frequency. The analysis unit may determine a second control signal to adjust the amplification time of the variable gain amplifier. The analysis unit may determine a third control signal to determine parameters of a digital down-converter in the data processing path. The analysis unit may determine the frequency of the clock signal that the clock generation module needs to output, and adjust the sampling rate of the analog-to-digital converter 130. The analysis unit may control the switch module and the multi-path switch to determine the data processing path that needs to be connected.

Furthermore, in some embodiments, the control module 140 may control the clock generation module to generate a clock signal with a specific frequency through the phase-locked loop. The control module 140 may select a clock signal (e.g., the clock signal CLK1 or CLK2) corresponding to the nuclide frequency for the data processing path according to the nuclide information that needs to be received currently.

In some embodiments, the analysis unit and the host computer may communicate through high-speed optical fibers. Correspondingly, the interior of the analysis unit may undergo a parallel-to-serial conversion, then undergo a photoelectric conversion, and finally connect to the host computer through the optical fibers. In some embodiments of the present disclosure, compared with a way of using an electrical connection for data transmission, a way of using the optical fibers for data transmission can greatly save the system wiring space. There may be no Electromagnetic Interference (EMI) caused by a long-distance electrical interconnection, which can reduce the cost.

In some embodiments, the signal acquisition device 100 may further include a counter module (also referred to as a DC counter) and a drive circuit. The counter module may output a digital pulse under the control of a third control signal. A signal for adjusting the adjustable capacitance unit may be generated after the digital pulse passes through the drive circuit.

The counter module may be a circuit module that outputs an adjustable periodic digital pulse. In some embodiments, the counter module may adjust parameters (e.g., a frequency, a duty ratio) of the digital pulse according to the third control signal. In some embodiments, the counter module may adjust the duty ratio of the digital pulse to control an analog voltage output by the drive circuit. Exemplarily, the duty ratio of the digital pulse may be directly proportional to the analog voltage. In some embodiments, the drive circuit may include a low-pass filter (LPF) and a drive amplifier, where the low-pass filter and the drive amplifier may filter the digital pulse and output a signal for adjusting the capacitance value of the adjustable capacitance unit.

In some embodiments, the counter module may generate the digital pulse by performing frequency division with m1 times on a clock signal (e.g., the clock signal CLK3 shown in FIG. 4) generated from the clock generation module and determining the control manner of the duty ratio. Exemplarily, the frequency of the digital pulse may be CLK3 and the duty ratio may be m0/m1 wherein m0 and m1 are different frequency division times m0 of the counter module.

In some embodiments, the difference between the nuclide frequency of the magnetic resonance signal and any harmonic frequency of the digital pulse may be not less than 5% of the nuclide frequency. That is, any harmonic of the digital pulse may not fall in the frequency band of the nuclide frequency corresponding to the current analog-to-digital processing path, and there may be a difference between the nuclide frequencies of different nuclides. In this way, interference coupling between the magnetic resonance signal and other magnetic resonance signals may be avoided. If the frequency of the digital pulse is not set according to the nuclide frequency of the nuclear magnetic resonance, even if the digital pulse is filtered by the drive circuit, there may be a possibility of leakage to the adjustable capacitor unit C1, and a leaked high-frequency component may still be captured by the receiving link. If the high-frequency component is mixed into the multi-core frequency band of the magnetic resonance signal, the recognition accuracy of the magnetic resonance signal by the receiving link of the signal acquisition device 100 may be reduced, resulting in inaccurate signal acquisition.

For example, the frequency of the clock signal CLK3 may be 200 MHz, the frequency division time m1 of the counter module may be 40, the frequency division time m0 of the counter module may be 0˜40, and the frequency of the digital pulse may be 5 MHz. If the frequency range of the magnetic resonance device with a B0 field strength of 3 T is between 127.5 MHz and 128.5 MHz, additive interference of any harmonic of the digital pulse with a frequency of 5 MHz may not fall within the imaging range of the magnetic resonance device. Moreover, since the signal frequency band of the magnetic resonance device with the B0 field strength of 3 T is generally less than 1 MHz, and far less than 5 MHz, multiplicative interference modulated into the link through the adjustable capacitor unit may not fall within the imaging range of the magnetic resonance device. Furthermore, the LPF may not perform excessively deep filtering, but retain the DC voltage in the digital pulse through low-pass filtering. In some embodiments, the DC voltage magnitude may be directly proportional to m0/m1.

In some embodiments of the present disclosure, a layout and wiring of a single-board circuit of the analysis unit may not need special design considerations for suppression of a coupling of an AC pulse signal output by the counter, which reduces the design difficulty and facilitates a more compact circuit layout, thereby saving space and cost. In addition, since the adjustable capacitor unit is located in an output terminal of the variable gain amplifier, the out-of-band harmonic interference coupled into the output terminal of the variable gain amplifier may be much smaller than the amplified maximum magnetic resonance signal. Therefore, there may be no out-of-band blocking distortion.

It should be noted that the spatial positions of the LPF may be interchanged with the Opamp in the drive circuit, or may be replaced by an active filter that integrates a filtering mechanism into a closed-loop feedback network of the operational amplifier.

In some embodiments, the signal acquisition device 100 may also include the analog-to-digital converter, and the analog-to-digital converter may be disposed between the analysis unit and the adjustable capacitance unit, which is configured to output a signal for adjusting the adjustable capacitance unit under the control of a first control signal. In some embodiments, the analog-to-digital converter may convert a signal output by the Opamp into an analog voltage signal, so that the adjustable capacitance unit may adjust the capacitance value according to the analog voltage signal.

In some embodiments, the control module 140 may further include an amplitude-phase nonlinear distortion compensation module, which is configured to compensate for the amplitude-phase distortion of the signal generated by the adjustable capacitor unit. Exemplarily, as shown in FIG. 4, the amplitude-phase nonlinear distortion compensation module (denoted as A-P-Correct in FIG. 4) may be disposed between the multi-path switch S2 and the host computer.

In some embodiments, a distortion curve may be obtained through testing first, and then an amplitude-phase pre-distortion mechanism may be introduced for compensation according to the distortion curve. For example, different capacitance values of the adjustable capacitor unit may correspond to different distortion curves. The control module 140 may pre-store calibration parameters (e.g., a calibration curve, a compensation manner, or a coefficient) corresponding to each distortion curve, so as to establish a correspondence relationship between the capacitance value of the adjustable capacitance unit and the calibration parameters. The calibration curve, the compensation manner, or the coefficient may be determined by pre-measuring linear distortions of the adjustable capacitor unit under a plurality of capacitance values. In a process of compensation, the calibration curve corresponding to each distortion curve may be retrieved directly based on the capacitance value of the adjustable capacitor unit for supplement, so as to improve the efficiency of the distortion compensation. In this process, the linear distortion of the adjustable capacitor unit may be used to compress the amplitude of the magnetic resonance signal to adapt to the dynamic range of the analog-to-digital converter, and then the amplitude may be decompressed through the calibration parameters, which can improve a processing capability of the receiving link for the magnetic resonance signal as a whole. In some embodiments, high-order harmonics caused by the linear distortion may be filtered out by a digital down-converter (e.g., the digital down-conversion module DDC1 and the digital down-conversion module DDC2).

In some embodiments, the signal matching module 120 may also include a power divider, which may be configured to perform power division on the magnetic resonance signal and send at least one signal after the power division to the adjustable capacitance unit and the radio frequency transformer.

The power divider may be a component that divides the power of the magnetic resonance signal. In some embodiments, the power divider may divide the magnetic resonance signal into at least one power-divided signal (i.e., the at least one signal after the power division aforementioned), so that the power of each power-divided signal may be adapted to the dynamic range of the analog-to-digital converter. Correspondingly, the control module 140 may add up at least one digitized power-divided signal in the digital domain, so as to restore the signal.

In some optional embodiments, there may be one power divider, and the power divider may be disposed at the input terminal of the adjustable capacitance unit. The power divider may be configured to perform the power division on the magnetic resonance signal transmitted by the signal acquisition module 110 and output the at least one power-divided signal. Correspondingly, there may be at least one adjustable capacitor unit and at least one radio frequency transformer, so as to perform differential processing on each power-divided signal. In some embodiments, each output branch of the power divider may be connected with an adjustable capacitor unit and a radio frequency transformer, so that the adjustable capacitor unit may cooperate with the radio frequency transformer on the each output branch to perform the differential processing on the power-divided signal of the output branch, and a power-divided signal after the differential processing may be output. Further, in some embodiments, there may be at least one analog-to-digital converter, and the analog-to-digital converter may perform the analog-to-digital conversion on at least one power-divided signal after the differential processing.

Exemplary, in the signal acquisition device 100 in FIG. 4, the power divider may be disposed on the input terminal of the adjustable capacitance unit C1 and configured to perform the power division on the magnetic resonance signal output by the VGA. The power divider may output the power-divided signal through at least one output branch. Each output branch may be connected to the matching adjustable capacitor unit C1, the non-magnetic core balun transformer T1, and the non-magnetic core coreless balun transformer T2 to perform the differential processing on the each power-divided signal. In the embodiments of the present disclosure, there may be one power divider to reduce the amplitude and power of the signal in a manner of performing the power division first and then performing the differential processing, so that the each power-divided signal after the differential processing may be adapted to the dynamic range of the analog-to-digital converter. In some optional embodiments, there may be a plurality of power dividers, and the plurality of power dividers may also be respectively set at the output terminal of the radio frequency transformer, so as to respectively perform power division on the differential signal output by differential terminals (which may include N-terminal and P-terminal) of the radio frequency transformer and output at least one differential signal after the power division, so that each differential signal after the power division may be adapted to the dynamic range of the analog-to-digital converter. Correspondingly, in some embodiments, there may be at least one analog-to-digital converter, and each analog-to-digital converter may perform the analog-to-digital conversion on one of the at least one differential signal after the power division.

Exemplary, as shown in FIG. 4, two power dividers may be respectively disposed on two differential output terminals of the non-magnetic core balun transformer T2 (i.e., the radio frequency transformer). Each power divider may perform the power division on a differential signal output by the non-magnetic core balun transformer T2 and output at least one differential signal after the power division through at least one output branch. In this situation, there may be no need to set a plurality of groups of adjustable capacitors unit and radio frequency transformers. The amplitude and power of the signal may be reduced by using a manner of performing the differential processing first and then performing the power division, so that each power-divided signal after the differential processing may be adapted to the dynamic range of the analog-to-digital converter. In some optional embodiments, the power divider may also be disposed between the adjustable capacitor unit and the radio frequency transformer.

In some embodiments of the present disclosure, a magnetic resonance signal corresponding to a multi-nuclide frequency may realize the broadband tuning and matching based on the cooperation of the adjustable capacitor unit and the radio frequency transformer. The power divider may further divide the magnetic resonance signal into at least two power-divided signals, so that the power of the power-divided signals may be used for power boosting of the analog-to-digital converter, thereby improving a dynamic range of signal reception.

An exemplary magnetic resonance device is provided below, and more descriptions of the above-mentioned signal acquisition apparatus 100 are described in detail.

In some embodiments, the magnetic resonance device may include a scanner for generating a main magnetic field and capable of exciting nuclear spins of various specific nuclides of a detection object in the main magnetic field to generate the magnetic resonance signal. In some embodiments, the magnetic resonance device may also include a radio frequency receiving coil, which may be connected to the scanner to receive the magnetic resonance signal. In some embodiments, the magnetic resonance device may also include a receiving link containing a gain amplifier, the signal matching module 120, and the analog-to-digital converter 130. The gain amplifier may be connected to the receiving coil to amplify the magnetic resonance signal. The signal matching module 120 may include the adjustable capacitor unit and the radio frequency transformer connected to each other. The adjustable capacitor unit may be connected to the gain amplifier, and the capacitance value of the adjustable capacitor unit may be adjusted to cooperate with the radio frequency transformer to receive an amplified magnetic resonance signal and convert the amplified magnetic resonance signal into the analog differential signal. The analog-to-digital converter 130 may be connected to the radio frequency transformer and may be configured for converting the analog differential signal into the digital signal. The control module 140 may be configured to process the digital signal to generate the K-space data corresponding to the magnetic resonance signal. The control module 140 may include the analysis unit, and the analysis unit may analyze the instruction of the host computer and generate a control signal (e.g., a first control signal, a second control signal, and a third control signal).

In some embodiments, the scanner may be configured as an electronic device that generates a magnetic field to excite the nuclear spins of various specific nuclides to generate the magnetic resonance signal, so as to facilitate acquisition by the above-mentioned signal acquisition device 100. In some embodiments, the modules or components in the magnetic resonance device may be realized by the signal acquisition device 100 and its modules or components shown in the above-mentioned FIGS. 3-6B, which will not be repeated here.

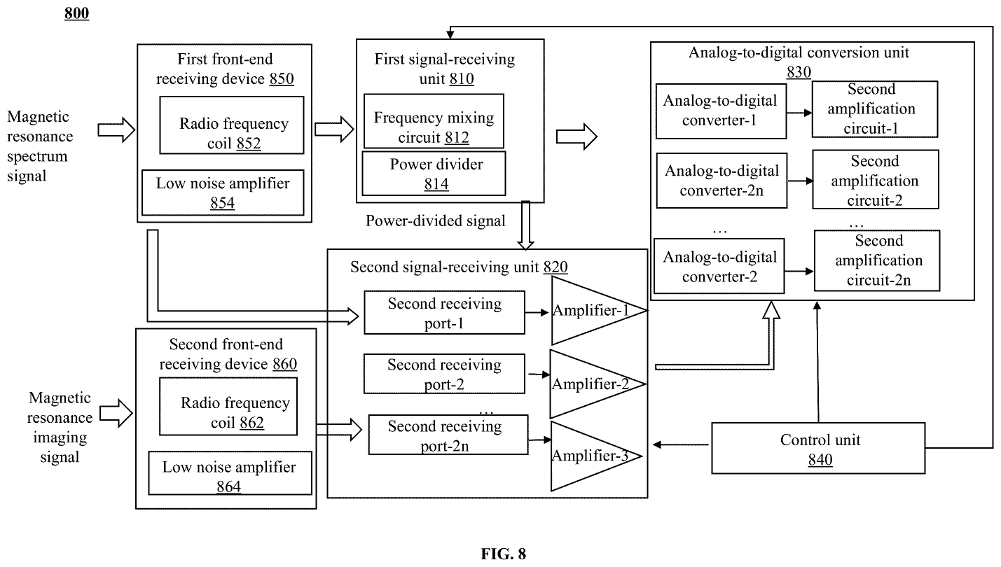

FIG. 7 is a flowchart illustrating a signal acquisition process according to some embodiments of the present disclosure. In some embodiments, a process 700 may be implemented by a signal acquisition device (e.g., the signal acquisition device 100).

In some embodiments, the process 700 may include following operations.

In 710, the signal acquisition device may be configured to obtain a magnetic resonance signal, at least part of which may be generated by exciting one or more specific nuclides.

In some embodiments, the signal acquisition device may use the radio frequency receiving coil to receive the magnetic resonance signal of the specific nuclide frequency, and then filter the magnetic resonance signal of the specific nuclide frequency through the anti-aliasing filter. In some embodiments, the magnetic resonance signal may carry the specific nuclide information. In some embodiments, the control module of the signal acquisition device may receive a plurality of magnetic resonance signals with different nuclide information by using different signal acquisition modules.

In some embodiments, the signal acquisition device may also use the gain amplifier to amplify the magnetic resonance signal according to the second control signal. Further, in some embodiments, the signal acquisition device may adjust the gain of the variable gain amplifier to adapt to signals with different amplitudes, so that the signal amplitude may be stable to use the dynamic range of the analog-to-digital converter as much as possible.

In some embodiments, the operation 710 may be implemented by a signal acquisition module of the signal acquisition device. For more descriptions of the signal acquisition module, please refer to the relevant descriptions in the above-mentioned FIGS. 3-4, which will not be repeated here.

In 720, an instruction of a host computer may be analyzed and a first control signal may be generated, wherein the first control signal may be configured to adjust a capacitance value of an adjustable capacitance unit, so as to cooperate with a radio frequency transformer to process the magnetic resonance signal corresponding to specific nuclide information.

In some embodiments, the counter module of the signal acquisition device may output the digital pulse under the control of the third control signal, a signal for adjusting the adjustable capacitance unit may be generated after the digital pulse passes through the drive circuit. In some embodiments, the operation 720 may be implemented by the control module of the signal acquisition device. For more descriptions of the control module, please refer to the relevant descriptions in the above-mentioned FIGS. 3-4, which will not be repeated here.

In 730, K-space data corresponding to the magnetic resonance signal may be generated by processing the magnetic resonance signal.

In some embodiments, the signal acquisition device may use the adjustable capacitance unit to adjust the capacitance value according to the first control signal, so as to cooperate with the radio frequency transformer to receive the magnetic resonance signal corresponding to the specific nuclide information and convert the magnetic resonance signal into the analog differential signal. In some embodiments, the signal acquisition device may adjust the capacitance value of the adjustable capacitor unit to cooperate with the radio frequency transformer to adjust the receiving frequency band of the receiving link of the signal acquisition device, so as to use the same receiving link to receive a plurality of magnetic resonance signals carrying the different nuclide information.

In some embodiments, the signal acquisition device may use the analog-to-digital converter to sample the analog differential signal according to the clock signal to obtain the digital signal. In some embodiments, the signal acquisition device may also select a data processing path corresponding to the specific nuclide information of the magnetic resonance signal from a plurality of data processing paths, and extract, filter, and demodulate the digital signal to obtain the K-space data. In some embodiments of the present disclosure, the signal acquisition device may design the receiving link based on the direct sampling architecture of the analog-to-digital converter, while reducing the overall volume of the signal acquisition device, the signal demodulation in the digital domain may be realized and the K-space data may be obtained.

In some embodiments, the operation 730 may be implemented by the signal matching module, the analog-to-digital converter, and the control module of the signal acquisition device. For more descriptions of the signal matching module, the analog-to-digital converter, and the control module, please refer to the relevant descriptions in the above-mentioned FIGS. 2-6B, which will not be repeated here.

It should be noted that the above description about the process 700 is only for illustration and description, and does not limit the scope of application of the present disclosure. For those skilled in the art, various modifications and changes may be made to the process 700 under the guidance of the present disclosure. However, such modifications and changes are still within the scope of the present disclosure. For example, operation 720 may be performed before operation 710 or may be performed before operation 730, so as to timely change the receiving frequency band of the signal acquisition module according to the instruction of the host computer and to collect magnetic resonance signals with other specific nuclide frequencies.

The possible beneficial effects of the embodiments of the present disclosure may include but may not limited to: (1) The receiving link may be designed based on the direct sampling architecture of the analog-to-digital converter. There may be no need to set a mixer in the receiving link, and the signal demodulation may be performed in the digital domain to generate the K-space data corresponding to the nuclide information, thereby shortening the receiving link, reducing the overall volume of the signal acquisition device, and improving the integration degree. (2) The signal matching module may select the specific narrowband signal for transmission under the broadband through the cooperation of the adjustable capacitor unit and the radio frequency transformer, which may realize the broadband tuning and matching with a simple architecture. At the same time, the intrusion of radio frequency interference can be slowed down through a narrow receiving frequency band, so that the signal acquisition device can work stably. (3) When it is necessary to obtain magnetic resonance signals corresponding to other nuclide information, the signal acquisition device may not need to replace the entire receiving link, and may replace the signal acquisition module and adjust the capacitance value of the adjustable capacitance unit, so that the adjustable capacitor unit may cooperate with the radio frequency transformer to complete the adjustment of the receiving frequency band, thereby achieving the purpose of receiving a plurality of different magnetic resonance signals using the same link architecture.

A magnetic resonance signal may be released by at least one nuclide of the target object in a form of a wireless wave under action(s) of a magnetic field (B0) and a radio frequency field (B1). In some embodiments, the target object may be a human body, an organ, an organism, a subject, a phantom, a region of interest, a lesion, a tumor, or the like. The at least one nuclide may include an atomic nucleus that makes up the target object. For example, the at least one nuclide may include but not be limited to, a hydrogen nucleus and/or a polynuclear. The polynuclear refers to a nuclide with more than one proton and neutron in the atomic nucleus, for example, a helium nucleus, an oxygen nucleus, a nitrogen nucleus, a fluorine nucleus, a sodium nucleus, a potassium nucleus, a chlorine nucleus, a phosphorus nucleus, a silicon nucleus, etc. Specifically, after the at least one nuclide of the target object is aligned with a direction of the magnetic field under the action of the magnetic field, resonance may occur under the action of the radio frequency field, thereby absorbing energy and generating a flip angle. After the radio frequency field is turned off, the at least one nuclide may return to alignment with the direction of the magnetic field under the action of the magnetic field, and at the same time, absorbed energy may be released in a form of a magnetic resonance signal.

In some embodiments, the magnetic resonance imaging device may obtain a nuclear magnetic resonance image of the target object based on the magnetic resonance signal of a nuclide (for example, the hydrogen nucleus and/or polynuclear) in the target object. In some embodiments, a magnetic resonance spectrometer may estimate a content of organic compounds in the target object based on the magnetic resonance signal of at least one atomic nucleus in the target object. In some embodiments, a magnetic resonance spectroscopy imaging device may obtain a magnetic resonance spectroscopy image of the target object based on a magnetic resonance signal of the at least one atomic nucleus in the target object.

The magnetic resonance spectrometer and the magnetic resonance spectroscopy imaging device may generally include a receiving path to receive the magnetic resonance signal of the nuclide and need to have a higher signal strength receiving range, a higher signal-to-noise ratio, and a higher sensitivity to identify different atomic nucleus signals. Therefore, a magnetic resonance signal processing device is needed to process the magnetic resonance signal in the magnetic resonance spectroscopy analysis and/or magnetic resonance spectroscopy imaging to achieve a higher dynamic range and a higher signal-to-noise ratio.

The magnetic resonance imaging device may generally require a plurality of receiving paths to receive magnetic resonance signals of the nuclide. In addition, a working frequency of the receiving paths of the magnetic resonance imaging device may be different from that of the magnetic resonance spectrometer and that of the magnetic resonance spectroscopy imaging device. Therefore, if a magnetic resonance signal processing device needs to have the function of processing the magnetic resonance signal (i.e., the magnetic resonance imaging signal) for MR imaging and the magnetic resonance signal (i.e., the magnetic resonance spectrum signal) for spectroscopy analysis and/or spectroscopy imaging, the magnetic resonance signal processing device may need to have a higher signal-to-noise ratio, multiple receiving paths, and a high dynamic range, under the same hardware architecture.

FIG. 8 is a schematic diagram illustrating an exemplary application scenario of a magnetic resonance signal processing device 800 according to some embodiments of the present disclosure. In some embodiments, the signal receiving unit may include a first signal-receiving unit and/or a second signal-receiving unit. The magnetic resonance signal processing device 800 is referred to as a device 800 for brevity. As shown in FIG. 8, the device 800 may include a first signal-receiving unit 810, a second signal-receiving unit 820, an analog-to-digital conversion unit 830, and a control unit 840.

As mentioned above, the magnetic resonance signal is the energy released by at least one nuclide of the target object in the form of a wireless wave under the action of the magnetic field (B0) and the radio frequency field (B1), which may include a magnetic resonance spectrum signal and a magnetic resonance imaging signal. The magnetic resonance device may be a device that provides the magnetic field and radio frequency field.

In some embodiments, the magnetic resonance device may include a magnetic resonance imaging device, a magnetic resonance spectrometer, a magnetic resonance spectroscopy imaging device, or the like. In some embodiments, the range of the magnetic field and the radio frequency field provided by the magnetic resonance imaging device may be narrower, and the range of the magnetic field and the radio frequency field provided by the magnetic resonance spectrometer and the magnetic resonance spectroscopy imaging device may be wider.

A front-end receiving device may be a device for receiving the magnetic resonance signal in the magnetic resonance device. Exemplarily, as shown in FIG. 8, the front-end receiving device may include a first front-end receiving device 850, and a second front-end receiving device 860. The first front-end receiving device 850 may be at least one of a receiver in the magnetic resonance spectrometer and a signal receiving system in the magnetic resonance spectroscopy imaging device. The second front-end receiving device 860 may be a signal receiving system in the magnetic resonance imaging device.

As shown in FIG. 8, in some embodiments, the first front-end receiving device 850 may include a radio frequency coil 852 and a low noise amplifier 854. In some embodiments, the second front-end receiving device 860 may include a radio frequency coil 862 and a low noise amplifier 864.

The radio frequency coils (852 and/or 862) may be coils for collecting magnetic resonance signals (the magnetic resonance imaging signal and/or magnetic resonance spectrum signal). Exemplarily, the radio frequency coil 852 in the first front-end receiving device 850 (such as the magnetic resonance spectrometer and/or the magnetic resonance spectroscopy imaging device) may collect the magnetic resonance spectrum signal. As another example, the radio frequency coil 862 in the second front-end receiving device 860 (such as the magnetic resonance imaging device) may collect the magnetic resonance imaging signal.

The low noise amplifiers (854 and/or 864) may be components configured to amplify signals without amplifying noise. In some embodiments, a low noise amplifier may amplify the magnetic resonance signal collected by a radio frequency coil. For example, the low noise amplifier 854 may amplify a magnetic resonance spectrum signal collected by the radio frequency coil 852. As another example, the low noise amplifier 864 may amplify a magnetic resonance imaging signal collected by the radio frequency coil 862.

In some embodiments, an amplification coefficient of a low noise amplifier may be determined based on the strength of the magnetic field in the magnetic resonance device. Exemplarily, the greater the strength of the magnetic field in the magnetic resonance device, the stronger the magnetic resonance signal, and the smaller the amplification coefficient.

In some embodiments, the first front-end receiving device 850 may amplify the magnetic resonance spectrum signal collected from the magnetic resonance spectrometer and/or the magnetic resonance spectroscopy imaging device and send it to the first signal-receiving unit 810. The second front-end receiving device 860 may send the magnetic resonance imaging signal collected from the magnetic resonance imaging device to the second signal-receiving unit 820.

The first signal-receiving unit 810 may be configured to process the magnetic resonance spectrum signal collected by the first front-end receiving device 850. In some embodiments, an input of the first signal-receiving unit 810 may include the magnetic resonance spectrum signal, and an output of the first signal-receiving unit 810 may include a power-divided signal.

In some embodiments, the first signal-receiving unit 810 may include a frequency mixing circuit 812 and a power divider 814.

The frequency mixing circuit 812 may be configured to divide the magnetic resonance spectrum signal into a first signal and a second signal. For detailed descriptions of the frequency mixing circuit 812, please refer to the detailed descriptions of a frequency mixing circuit 920 in a device 900 for processing a magnetic resonance signal in FIG. 9, which will not be repeated here.

The power divider 812 may be configured to divide the magnetic resonance spectrum signal into at least two power-divided signals. In some embodiments, a power divider 930 may be configured to divide the first signal into at least two first power-divided signals and divide the second signal into at least two second power-divided signals. For detailed descriptions of the power divider 812, please refer to detailed descriptions of the power divider 930 in the device 900 in FIG. 9, which will not be repeated here.

In some embodiments, the first signal-receiving unit 810 may further include a first receiving port and a first amplification circuit. For detailed descriptions of the first receiving port and the first amplification circuit, please refer to the detailed descriptions of a first receiving port 910 and a first amplification circuit 940 in the device 900 in FIG. 9, which will not be repeated here.

For more descriptions about the first signal-receiving unit 810, please refer to the relevant descriptions of the device 900 in FIG. 9, which will not be repeated here.

The second signal-receiving unit 820 may be configured to process the magnetic resonance imaging signal collected by the second front-end receiving device 860. In some embodiments, an input of the second signal-receiving unit 820 may include the magnetic resonance imaging signal, and an output may include an imaging digital signal. In some embodiments, the input of the second signal-receiving unit 820 may include the power-divided signal output by the first signal-receiving unit 810, and the output may include a power-divided digital signal.

In some embodiments, the second signal-receiving unit 820 may include at least two receiving ports, (i.e., at least two second receiving ports). The second receiving ports may be configured to receive the magnetic resonance imaging signal collected by the second front-end receiving device 860.

In some embodiments, the second front-end receiving device 860 may include a signal receiving system of the magnetic resonance imaging device. For detailed descriptions of the second front-end receiving device, please refer to the above descriptions of FIG. 8 and related descriptions thereof, which will not be repeated here.

The magnetic resonance imaging signal may be a magnetic resonance signal for MR imaging induced by the nuclide (for example, the hydrogen nucleus and/or polynuclear) of the target object under the action of the magnetic field and the radio frequency field. It may be understood that the power and amplitude range of the magnetic resonance imaging signal may be relatively fixed. For example, the magnetic resonance imaging signal may have a frequency of 800 MHZ, a power of 4 dBm, and a maximum amplitude (peak-to-peak) of 1V.

In some embodiments, a second receiving port may input the magnetic resonance imaging signals received by different radio frequency coils 862 of the second front-end receiving device 860 into different analog-to-digital converters, respectively. For example, a magnetic resonance imaging signal-1 received by a radio frequency coil 862-1 may be input into an analog-to-digital converter-1, a magnetic resonance imaging signal-2 received by a radio frequency coil 862-2 may be input into an analog-to-digital converter-2 . . . and a magnetic resonance imaging signal-2n received by a radio frequency coil 862-2n may be input into an analog-to-digital converter-2n.

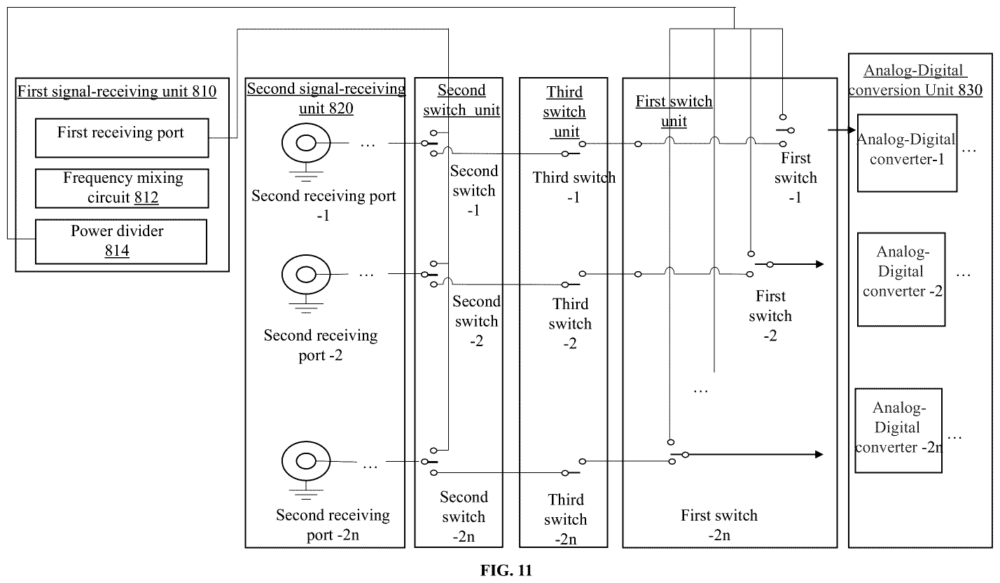

In some embodiments, a second receiving port may be configured to receive the magnetic resonance spectrum signal or the power-divided signal of the magnetic resonance spectrum signal through a switch unit. For detailed descriptions of receiving the magnetic resonance spectrum signal or the power-divided signal of the magnetic resonance spectrum signal by the second receiving port, please refer to FIG. 11 and its related descriptions, which will not be repeated here.

In some embodiments, one of the at least two receiving ports may be a target receiving port, which may be further configured to receive the magnetic resonance spectrum signal collected by the first front-end receiving device 850. As shown in FIG. 8, the second receiving port-1 may be the target receiving port, which may be further configured to receive the magnetic resonance spectrum signal collected by the first front-end receiving device 850.

In some embodiments, an amplifier may be provided after each second receiving port.

The amplifier may be a component that amplifies a magnetic resonance imaging signal. In some embodiments, an input of the amplifier may be the magnetic resonance imaging signal output by the corresponding second receiving port, and an output of the amplifier may be an amplified magnetic resonance imaging signal. In some embodiments, the amplifier may be a fixed gain amplifier or a variable gain amplifier. For detailed descriptions of the fixed gain amplifier and the variable gain amplifier, please refer to FIG. 9 and its related descriptions, which will not be repeated here. As for the example provided above, the amplifier may amplify the amplitude of the magnetic resonance imaging signal from 0.01 mV to 0.1 mV.

In some embodiments, the second signal-receiving unit 820 may include an adjustable capacitance unit and a radio frequency transformer connected to each other, and the adjustable capacitance unit may adjust the capacitance value according to a fourth control signal to cooperate with the radio frequency transformer to receive the magnetic resonance imaging signal and convert the magnetic resonance imaging signal into an analog signal.

The radio frequency transformer is a transformer that works in a radio frequency range, which may be configured to realize the transmission of radio frequency energy and convert a single-ended signal into an analog differential signal, such as converting the magnetic resonance imaging signal into an analog differential signal. The adjustable capacitance unit may include variable capacitors and other capacitors. In some embodiments, the adjustable capacitance unit may change the applied voltage of the variable capacitor according to the fourth control signal from the drive circuit, so as to adjust its own capacitance value to cooperate with the radio frequency transformer to complete the adjustment of the receiving frequency band. The adjustable capacitance unit may receive the magnetic resonance imaging signal corresponding to the specific nuclide information, so as to realize the direct acquisition of multi-nuclear magnetic resonance signals. Exemplarily, the adjustable capacitance unit may adjust the tuning range of the radio frequency transformer by changing its own capacitance value, so that the nuclide frequency corresponding to the magnetic resonance imaging signal may be located at the best matching point between the adjustable capacitance and the balun transformer, thereby realizing the broadband resonance matching.

In some embodiments, for the device 800 shown in FIG. 8, the adjustable capacitance unit and the radio frequency transformer may be disposed at the output terminal of a second receiving port, and the differential processing may be performed on the magnetic resonance imaging signal output by the second receiving port, and the frequency of the magnetic resonance imaging signal may be selected and matched. In some embodiments, each second receiving port may be connected to an adjustable capacitance unit and a radio frequency transformer, so as to perform the differential processing on each magnetic resonance imaging signal. Correspondingly, in some embodiments, the radio frequency transformer may further include at least one differential output terminal, and each differential output terminal may be connected to an amplifier to amplify at least one magnetic resonance imaging signal after the differential processing.

Exemplarily, for the device 800 shown in FIG. 8, the second receiving port-1 may be connected to an adjustable capacitance unit-1 and a radio frequency transformer-1 in turn, and output a magnetic resonance imaging signal-1 after the differential processing and a magnetic resonance imaging signal-2 after the differential processing. The differential output terminal of the radio frequency transformer-1 may be connected to an amplifier-1 and an amplifier-2, respectively, so that the amplifier-1 may amplify the magnetic resonance imaging signal-1 after the differential processing, and the amplifier-2 may amplify the magnetic resonance imaging signal-2 after the differential processing.

It should be noted that, in some embodiments, the control unit 840 may obtain the analysis data (such as the K-space data) corresponding to the radio frequency of the nuclide by performing the signal processing such as extraction, filtering, and demodulation on the plurality of differential signals corresponding to the magnetic resonance imaging signal using the plurality of data processing paths. In some embodiments, the amplitude-phase distortion of the signal generated by the adjustable capacitor unit may be compensated by the amplitude-phase nonlinear distortion compensation module (A-P-Correct) of the control unit 840 to restore the signal, thereby improving the receiving dynamic range of the signal amplitude of the receiving link.

It should be noted that when only the first signal-receiving unit 810 is provided, the magnetic resonance signal processing device 800 may be applied to a magnetic resonance spectrometer and/or a magnetic resonance spectroscopy imaging device for processing a collected magnetic resonance spectrum signal. When only the second signal-receiving unit 820 is provided, the magnetic resonance signal processing device 800 may be applied to a magnetic resonance imaging device for processing a collected magnetic resonance imaging signal. When the first signal-receiving unit 810 and the second signal-receiving unit 820 are provided at the same time, the magnetic resonance signal processing device 800 may be applied to an imaging device such as the magnetic resonance spectrometer, the magnetic resonance spectroscopy imaging device, or the magnetic resonance imaging device for processing the collected magnetic resonance spectrum signal and the collected magnetic resonance imaging signal.

In some embodiments, the magnetic resonance signal processing device may include a third signal-receiving unit and a fourth signal-receiving unit, and the third signal-receiving unit may be configured to process a first magnetic resonance signal (e.g., the magnetic resonance spectrum signal) with a specific frequency. The fourth signal-receiving unit may be configured to process a second magnetic resonance signal (e.g., the magnetic resonance imaging signal) obtained according to a fifth control signal, and the second magnetic resonance signal may correspond to one of a plurality of magnetic resonance frequencies.

In some embodiments, the third signal-receiving unit may process a signal with a larger dynamic range (e.g., a magnetic resonance spectrum signal), and the fourth signal-receiving unit may process a signal with a smaller dynamic range (e.g., a magnetic resonance imaging signal). In some embodiments, the control unit 840 may select a corresponding signal-receiving unit to perform the signal processing according to the dynamic range of the magnetic resonance signal. For example, if the received magnetic resonance signal is a first magnetic resonance signal with a relatively large dynamic range (e.g., a magnetic resonance spectrum signal), the control unit 840 may use the third signal-receiving unit to perform the signal processing. Correspondingly, the third signal-receiving unit may perform the frequency mixing and power division on the first magnetic resonance signal, and then transmit a processed signal to a receiving port and an amplifier, so that the first magnetic resonance signal may adapt to the dynamic range of a subsequent analog-to-digital conversion. As another example, if the received magnetic resonance signal is a second magnetic resonance signal with a smaller dynamic range (e.g., a magnetic resonance imaging signal), the control unit 840 may use the fourth signal-receiving unit to perform the signal processing. Correspondingly, the fourth signal receiving unit may directly transmit the second magnetic resonance signal to a receiving port and an amplifier. Since the dynamic range of the second magnetic resonance signal is smaller, the second magnetic resonance signal may be adapted to the dynamic range of the subsequent analog-to-digital conversion unit. Therefore, there may be no need to perform the frequency mixing and power division on the second magnetic resonance signal.

In some optional embodiments, the third signal-receiving unit and the fourth signal-receiving unit may share part of a circuit for signal processing. If the received magnetic resonance signal is a first magnetic resonance signal with a larger dynamic range (e.g., a magnetic resonance spectrum signal), the control unit 840 may use the third signal-receiving unit and the fourth signal-receiving unit at the same time to perform the signal processing. For example, the third signal-receiving unit may perform the frequency mixing and power division on the first magnetic resonance signal, and then transmit the processed signal to the fourth signal-receiving unit. The fourth signal-receiving unit may transmit the signal to a receiving port and an amplifier, so that the first magnetic resonance signal may be adapted to the dynamic range of the subsequent analog-to-digital conversion. In this case, the third signal-receiving unit may be no need to separately set a receiving port and an amplifier, and the fourth signal-receiving unit may be configured to realize the signal transmission.

In some embodiments, the fourth signal-receiving unit may simultaneously process the first magnetic resonance signal and the second magnetic resonance signal in a manner of multi-path multiplexing. If a count of paths occupied by the first magnetic resonance signal from the third signal-receiving unit in the fourth signal-receiving unit is less than a total count of paths of the fourth signal-receiving unit, the fourth signal-receiving unit may use remaining paths not occupied by the first magnetic resonance signal to process the second magnetic resonance signal, thereby realizing the multi-path multiplexing.

In some embodiments, the third signal-receiving unit may include independent analog-to-digital conversion units to perform the analog-to-digital conversion on the first magnetic resonance signal and the second magnetic resonance signal. For example, the third signal-receiving unit may include a power divider, and the output terminal may be connected to a plurality of analog-to-digital converters, so that the analog-to-digital conversion may be performed on at least one magnetic resonance signal after the power division. The output terminal of the fourth signal-receiving unit may be connected to an analog-to-digital converter. The functions and structures of the third signal-receiving unit and the fourth signal-receiving unit may be similar to those of the above-mentioned first signal-receiving unit and the second signal-receiving unit. For more descriptions of the third signal-receiving unit and the fourth signal-receiving unit, please refer to the aforementioned related descriptions, which will not be repeated here.

The analog-to-digital conversion unit 830 may be a circuit that converts a magnetic resonance signal into a digital signal. In some embodiments, the analog-to-digital conversion unit 830 may include at least two analog-to-digital converters for performing the analog-to-digital conversion on the magnetic resonance spectrum signal and the magnetic resonance imaging signal. As shown in FIG. 8, the analog-to-digital conversion unit 830 may include the analog-to-digital converter-1, the analog-to-digital converter-2, . . . , and the analog-to-digital converter-2n.

In some embodiments, an analog-to-digital converter may sample a magnetic resonance signal that is continuous in the time domain and continuous in amplitude according to the sampling rate, and then convert the sampled magnetic resonance signal into a digital signal that is discrete in the time domain and digitized in the amplitude.

In some embodiments, a sampling clock frequency fₛ of the analog-to-digital converter and a maximum bandwidth range BWₘₐₓ of the magnetic resonance signal may satisfy a specific relationship (such as fₛ≥2×BWₘₐₓ), so that the analog-to-digital converter may convert the magnetic resonance signal into an undistorted digital signal.

In some embodiments, the sampling clock frequency of the analog-to-digital converter may be provided by a clock generation module. For a detailed description of the clock generation module, please refer to related descriptions of the control unit 840 below, which will not be repeated here. In some embodiments, the analog-to-digital converter may set a target frequency of the magnetic resonance signal based on the sampling clock frequency fₛ, so as to ensure the conversion effect of the analog-to-digital converter. Exemplarily, the bandwidth range (i.e., a target bandwidth range) BWₜ of the target frequency of the magnetic resonance signal and the sampling clock frequency fₛ of the analog-to-digital converter may satisfy the following relationship:

$${f}_{s} = ( 250 - 400 ) {BW}_{t} .$$

For example, if the sampling clock frequency of the analog-to-digital converter is 80 MHz (i.e., the sampling rate is 80 MSPS), the target bandwidth of the magnetic resonance signal input to the analog-to-digital converter may be between 200 KHz˜320 KHz.

In some embodiments, the analog-to-digital converter may be configured to perform the analog-to-digital conversion on the magnetic resonance imaging signal. In some embodiments, the input of the analog-to-digital converter may be the magnetic resonance imaging signal, and the output may be an imaging digital signal. For example, the magnetic resonance imaging signal-1, the magnetic resonance imaging signal-2, . . . , the magnetic resonance imaging signal-2n may be input into the analog-to-digital converter-1, the analog-to-digital converter-2, . . . , the analog-to-digital converter-2n, respectively, and an imaging digital signal-1, an imaging digital signal-2, . . . , an imaging digital signal-2n may be output.

In some embodiments, each analog-to-digital converter may be configured to perform an analog-to-digital conversion on at least one of two power-divided signals to obtain a power-divided digital signal. In some embodiments, each analog-to-digital converter may be configured to convert one of at least two first power-divided signals into a first power-divided digital signal, or convert one of at least two second power-divided signals into a second power-divided digital signal.

Specifically, the input of an analog-to-digital converter may be a power-divided signal (a first power-divided signal and/or a second power-divided signal), and the output may be a power-divided digital signal (a first power-divided digital signal and/or a second power-divided signal). For example, a first power-divided signal-1 (not shown), a first power-divided signal-2 (not shown), . . . , a first power-divided signal-n (not shown) may be input into the analog-to-digital converter-1, the analog-to-digital converter-2, . . . , and an analog-to-digital converter-n (not shown), respectively. The analog-to-digital converter may output a first power-divided digital signal-1 (not shown), a first power-divided digital signal-2 (not shown) shown), . . . , and a first power-divided digital signal-n (not shown), respectively. As another example, a second power-divided signal-1 (not shown), a second power-divided signal-2 (not shown), . . . , and a second power-divided signal-n (not shown) may be input into an analog-to-digital converter-(n+1) (not shown), an analog-to-digital converter-(n+2) (not shown), . . . , and the analog-to-digital converter-2n, respectively. The analog-to-digital converter may output a second power-divided digital signal-1 (not shown), a second power-divided Digital signal-2 (not shown), . . . , and a second power-divided digital signal-n (not shown), respectively.

In some embodiments, the analog-to-digital converter may be configured to perform the analog-to-digital conversion on the magnetic resonance spectrum signal. In some embodiments, the input of the analog-to-digital converter may be the magnetic resonance spectrum signal, and the output may be the spectrum digital signal. For example, a magnetic resonance spectrum signal (not shown) may be input into the analog-to-digital converter-1 through the second receiving port-1, and a spectrum digital signal may be output.

In some embodiments, the analog-to-digital conversion unit 830 may further include at least two second amplification circuits.

In some embodiments, a second amplification circuit may be located before an analog-to-digital converter and may be configured to amplify the magnetic resonance signal output by an amplifier and/or a second receiving port of the second signal receiving unit 820. Correspondingly, in some embodiments, the second amplification circuit may be an analog gain circuit. In some embodiments, the second amplification circuit may be configured to amplify the magnetic resonance signal. For detailed descriptions of amplifying the magnetic resonance signal by the second amplification circuit, please refer to relevant descriptions of the first amplification circuit and/or the amplifier, which will be not repeated here.

It may be understood that the aforementioned amplifier and the second amplification circuit may respectively perform a primary analog gain and a secondary analog gain on the magnetic resonance signal. The primary analog gain may roughly adjust and amplify the magnetic resonance signal, and the secondary analog gain may more finely adjust and amplify the magnetic resonance signal after the primary analog gain.

In some embodiments, the second amplification circuit may be configured to amplify multiple magnetic resonance imaging signals. For example, the magnetic resonance imaging signal-1, the magnetic resonance imaging signal-2, . . . , and the magnetic resonance imaging signal-2n may be respectively input into a second amplification circuit-1, a second amplification circuit-2, . . . , and a second amplification circuit-2n.

In some embodiments, the second amplification circuit may be configured to amplify multiple power-divided signals. For example, the first power-divided signal-1 (not shown), the first power-divided signal-2 (not shown), . . . , and the second power-divided signal-n (not shown) may be input into the second amplification circuit-1, the second amplification circuit-2, . . . , and the second amplification circuit-2n, respectively.

In some embodiments, the second amplification circuit may be configured to amplify the magnetic resonance spectrum signal. For example, a magnetic resonance spectrum signal (not shown) may be input to the second amplification circuit-1.

In some embodiments, the second amplification circuit may be located after an analog-to-digital converter and may be configured to amplify the digital signal output by the analog-to-digital converter. Correspondingly, in some embodiments, the second amplification circuit may be a digital gain circuit. In some embodiments, the second amplification circuit may be configured to amplify a digital signal. Specifically, the second amplification circuit may multiply each amplitude of the digital signal by a corresponding gain value, thereby amplifying the digital signal.

In some embodiments, the second amplification circuit may be configured to amplify an imaging digital signal. For example, a corresponding amplitude of an imaging digital signal at time t1 is 20, and the second amplification circuit may multiply the gain value by 20 to obtain a signal amplitude after a gain at this time. Exemplarily, the imaging digital signal-1 (not shown), the imaging digital signal-2 (not shown), . . . , and the imaging digital signal-2n (not shown) may be respectively input into the second amplification circuit-1, the second amplification circuit-2, . . . , and the second amplification circuit-2n.

In some embodiments, the second amplification circuit may be configured to amplify a power-divided digital signal. Exemplarily, the first power-divided digital signal-1 (not shown), the first power-divided digital signal-2 (not shown), . . . , and the second power-divided digital signal-n (not shown) may be respectively input to the second amplification circuit-1, the second amplification circuit-2, . . . , and the second amplification circuit-2n.

In some embodiments, the second amplification circuit may be configured to amplify a spectrum digital signal. Exemplarily, a spectrum digital signal (not shown) may be input into the second amplification circuit-1.

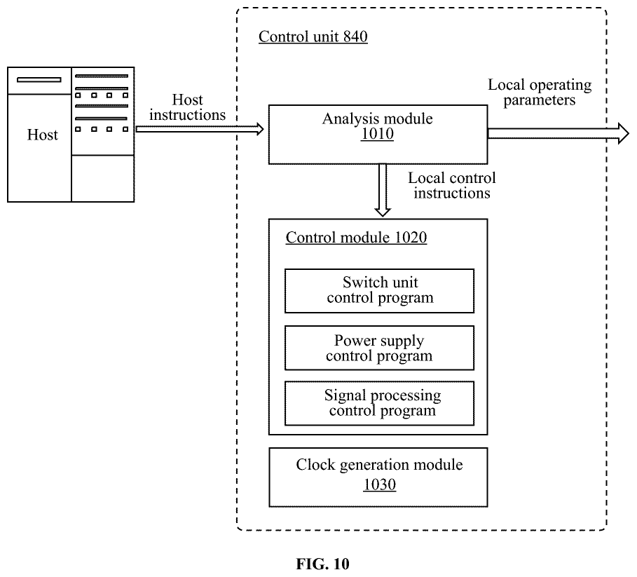

In some embodiments, the gain value and/or attenuation value of each component in the amplifier and/or the second amplification circuit may be determined by an analysis module. For detailed descriptions of the analysis module, please refer to FIG. 10 and the related descriptions thereof, which will not be repeated here.

In some embodiments, an anti-aliasing filter may also be provided between a second amplification circuit and an analog-to-digital converter. The anti-aliasing filter may filter the magnetic resonance signal (the magnetic resonance spectrum signal and/or the magnetic resonance imaging signal) to reduce an aliasing frequency signal in the magnetic resonance signal, thereby suppressing mirror image aliasing. In some embodiments, filtering parameters of the anti-aliasing filter may be determined by the analysis module. For detailed descriptions of the analysis module, please refer to FIG. 10 and the related descriptions thereof, which will not be repeated here.

The analog-to-digital converter and the second amplification circuit in some embodiments of the present disclosure may be configured to process both the magnetic resonance spectrum signal and the magnetic resonance imaging signal, which can expand the functions of components and save the hardware resources cost.

The control unit 840 may be configured to process the magnetic resonance spectrum signal after the analog-to-digital conversion to obtain a digital output signal corresponding to the magnetic resonance spectrum signal, and process the magnetic resonance imaging signal after the analog-to-digital conversion to obtain a digital output signal corresponding to the magnetic resonance imaging signal. In some embodiments, the control unit 840 may be configured to add the power-divided digital signals to obtain the digital output signal corresponding to the magnetic resonance spectrum signal. In some embodiments, the control unit 840 may be configured to obtain the digital output signal corresponding to the magnetic resonance spectrum signal by respectively adding at least two first power-divided digital signals and at least two second power-divided digital signals. In some embodiments, the control unit 840 may include a plurality of data processing paths, which are configured to perform signal processing such as extraction, filtering, and demodulation on a plurality of differential signals corresponding to the magnetic resonance imaging signal after the analog-to-digital conversion, so as to obtain analysis data (such as K-space data) corresponding to the nuclide frequency. In some embodiments, the control unit 840 may include an amplitude-phase nonlinear distortion compensation module, which may be configured to compensate for the amplitude-phase distortion of the signal generated by an adjustable capacitor unit.

For detailed descriptions of the control unit 840, please refer to FIG. 10 and related descriptions thereof, which will be not repeated here.

In some alternative embodiments, the control unit 840 may also be located in the first signal-receiving unit 810 and/or the second signal-receiving unit 820, or in other positions of the device 800, which may be not limited in this embodiment.

In some embodiments, the device 800 may include a first switch unit. The first switch unit may be configured to connect or disconnect a path between the first signal-receiving unit 810 and the analog-to-digital conversion unit 830. For detailed descriptions of the first switch unit, please refer to FIG. 11 and related descriptions thereof, which will not be repeated here.

In some embodiments, the device 800 may include a second switch unit. The second switch unit may be configured to connect or disconnect a path between the target receiving port and the first signal-receiving unit 810. For detailed descriptions of the second switch unit, please refer to FIG. 11 and related descriptions thereof, which will not be repeated here.

FIG. 9 is an exemplary schematic diagram illustrating an exemplary magnetic resonance signal processing device 900 according to some embodiments of the present disclosure. The magnetic resonance signal processing device 900 is referred to as a device 900 for brevity. As shown in FIG. 9, the device 900 may include a first receiving port 910, a frequency mixing circuit 920, a power divider 930, and a first amplification circuit 940. The device 900 may be configured for processing a magnetic resonance spectrum signal.

The first receiving port 910 may be a circuit for receiving the magnetic resonance spectrum signal.

The magnetic resonance spectrum signal may be a magnetic resonance signal for spectroscopy analysis and/or spectroscopy imaging induced by a nuclide of the target object under the action of the magnetic field and the radio frequency field with different strengths.

The same atomic nuclei of different compounds and/or different atomic nuclei of the same compound in the target object may have a difference (i.e., a chemical shift value) in resonance frequency under the action of different magnetic fields and radio frequency fields. Therefore, the magnetic resonance spectrum signal may be configured to infer the chemical composition of the target object.

In some embodiments, the first receiving port 910 may receive various magnetic resonance spectrum signals corresponding to various nuclides. In some embodiments, the first receiving port 910 may be configured to receive a magnetic resonance spectrum signals collected by the first front-end receiving device.

In some embodiments, the first front-end receiving device may include a receiver of the magnetic resonance spectrometer. For detailed descriptions of the first front-end receiving device, please refer to FIG. 8 and related descriptions thereof, which will be not repeated here.

In some embodiments, under the action of different magnetic fields, the frequency ranges of the resonances of the same nuclide may be different, the absorbed energies and the released energies may be different, and the amplitudes of the corresponding magnetic resonance spectrum signals may be correspondingly different, so the first receiving port may need to receive signals with different magnitudes for each nuclide. Exemplarily, under high magnetic fields with strengths of 4.7 T, 7 T, 9.4 T, 11.7 T, and 14.1 T, the corresponding resonance frequencies of the hydrogen nucleus may be 200 MHZ, 300 MHz, 400 MHz, 500 MHz, and 600 MHz, respectively, and the maximum amplitude (also referred to as the peak-to-peak value) of the corresponding magnetic resonance spectrum signal may be 0.1 mV, 0.15 mV, 0.2 mV, 0.25 mV, and 0.3 mV, respectively. Therefore, the first receiving port may need to be configured to receive magnetic resonance spectrum signals of the hydrogen nucleus with a maximum amplitude range of 0.1 mV-0.3 mV.

The first amplification circuit 940 may be a circuit for amplifying the magnetic resonance spectrum signals. In some embodiments, an input of the first amplification circuit 940 may be the magnetic resonance spectrum signal output from the first receiving port 910, and an output may be the amplified magnetic resonance spectrum signal. In some embodiments, the first amplification circuit 940 may include a variable gain amplifier (VGA). For example, the first amplification circuit 940 may include a combination of one or more of a digital step attenuator (DSA), a broad band high power gain block (BBHPGB), and a variable gain amplifying integrated circuit chip.

The digital step attenuator may be an electronic component configured to control an attenuation range of the amplitude of a magnetic resonance signal within a specified frequency range. In some embodiments, the digital step attenuator may include a resistive material and a control device. In some embodiments, the control device may be configured to control the range where the resistive material is connected to the first amplification circuit, so as to control the resistance value of the digital step attenuator, so that the digital step attenuator may attenuate the amplitude of the magnetic resonance signal in different sizes.

The broadband high power gain block may be an electronic component for providing greater gain to the power of a magnetic resonance signal within a wider frequency range.

The variable gain amplifying integrated circuit chip may be a chip that integrates one or more digital step attenuators and/or broadband high power gain blocks on a piece of a semiconductor material. In some embodiments, the variable gain amplifying integrated circuit chip may provide different types of gains for the amplitude of a magnetic resonance signal based on different components integrated therein.

In some embodiments, the first amplification circuit 940 may further include a fixed gain amplifier. The fixed gain amplifier may be an electronic component that provides a fixed gain to the amplitude of the magnetic resonance signal.

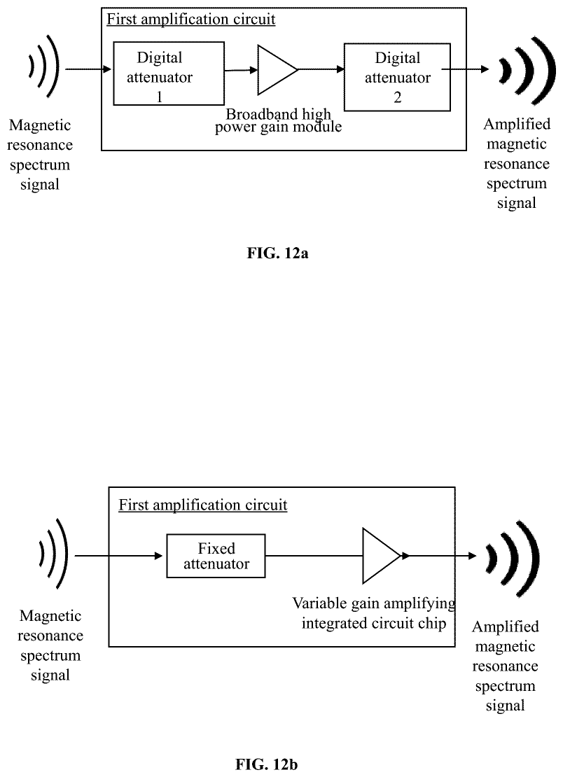

FIG. 12a is an exemplary schematic diagram illustrating a first amplification circuit according to some embodiments of the present disclosure. As shown in FIG. 12a, the first amplification circuit may include a digital step attenuator 1, a broadband high power gain block, and a digital step attenuator 2 in sequence. As mentioned above, the magnetic resonance spectrum signals of different nuclides received by a first receiving port may have different amplitudes. In some embodiments, the broadband high power gain block may provide gain for magnetic resonance signals in a wider frequency range, that is, it may be applied to provide gain for magnetic resonance spectrum signals with both smaller and larger amplitudes.

In some embodiments, the digital step attenuator 1 and the digital step attenuator 2 may provide a larger attenuation value for a magnetic resonance spectrum signal with a larger amplitude and provide a smaller attenuation value for a magnetic resonance spectrum signal with a smaller amplitude, so as to enable a maximum utilization of the dynamic range of a subsequent analog-to-digital converter.

In some embodiments of the present disclosure, using the first amplification circuit composed of the digital step attenuator and the broadband high power gain block, appropriate attenuation values and/or gain values may be configured for the received magnetic resonance signals of different atomic nuclei, so that the amplified magnetic resonance spectrum signal may achieve the best signal-to-noise ratio, and at the same time, the frequency of the magnetic resonance spectrum signal may not exceed the sampling clock frequency of the subsequent analog-to-digital converter.

FIG. 12b is an exemplary schematic diagram illustrating another first amplification circuit according to some embodiments of the present disclosure. As shown in FIG. 12b, the first amplification circuit may include a fixed attenuator and a variable gain amplifying integrated circuit chip. In some embodiments, the fixed attenuator may provide the same gain for magnetic resonance signals with different amplitudes. In some embodiments, the variable gain amplifying integrated circuit chip may integrate one or more digital step attenuators to provide a larger attenuation value for a magnetic resonance spectrum signal with a larger amplitude and a smaller attenuation value for a magnetic resonance spectrum signal with a smaller amplitude.

In some embodiments, the gain value and/or attenuation value of each component (such as the digital step attenuator, the broadband high power gain block, the fixed attenuator, and the variable gain amplifying integrated circuit chip) in the first amplification circuit may be determined through the analysis module. For detailed descriptions of the analysis module, please refer to the related descriptions of the control unit 840, which will not be repeated here.

Exemplarily, the first amplification circuit may amplify the maximum amplitudes of magnetic resonance spectrum signals of the hydrogen nucleus with the maximum amplitudes of 0.1 mV, 0.15 mV, 0.2 mV, 0.25 mV, and 0.3 mV to 0.4 mV.

In some embodiments of the present disclosure, based on the first amplifying circuit, different gain values and/or attenuation values may be provided for magnetic resonance spectrum signals with different amplitudes corresponding to different atomic nuclei, which may ensure that magnetic resonance spectrum signals with different amplitudes can be applicable to the analog-to-digital converter after being amplified, thereby improving the application range of the analog-to-digital converter.

The frequency mixing circuit 920 may be a circuit that converts the frequency of a magnetic resonance signal. In some embodiments, the frequency mixing circuit 920 may divide the magnetic resonance spectrum signal (or the amplified magnetic resonance spectrum signal) into a first signal and a second signal.

The first signal and the second signal may be magnetic resonance spectrum signals with a target frequency. In some embodiments, the target frequency may be determined based on the sampling clock frequency of the analog-to-digital converter. For detailed descriptions of the analog-to-digital converter, please refer to FIG. 10 and related descriptions thereof, which will not be repeated here.

In some embodiments, the mixing circuit may include a first mixer and a second mixer. The first mixer and the second mixer may be mixers for converting the magnetic resonance spectrum signal (or the amplified magnetic resonance spectrum signal) into the first signal and the second signal, respectively. In some embodiments, the mixer (either the first mixer or the second mixer) may include a nonlinear element, a local oscillator, and a bandpass filter. As shown in FIG. 9, the first mixer may include a local oscillator 921 connected to a nonlinear element 923, and the nonlinear element 923 connected to a bandpass filter 925. The second mixer may include a local oscillator 922 connected to a nonlinear element 924 and the nonlinear element 924 connected to a bandpass filter 926.

A local oscillator (the local oscillator 921 and/or 922) may generate a high-frequency equal-amplitude signal whose frequency is one middle frequency higher than the received signal. Specifically, the local oscillator 921 may generate a first high-frequency equal-amplitude signal whose frequency is one middle frequency higher than a magnetic resonance spectrum signal (or an amplified magnetic resonance spectrum signal). The local oscillator 922 may generate a second high-frequency equal-amplitude signal whose frequency is one middle frequency higher than a magnetic resonance spectrum signal (or an amplified magnetic resonance spectrum signal). The first high-frequency equal-amplitude signal and the second high-frequency equal-amplitude signal may be quadrature signals. In some embodiments, the local oscillator(s) (921 and/or 922) may include, but may not limited to, an LC transistor oscillator, a digital oscillator, or the like.

In some embodiments, the first high-frequency equal-amplitude signal and the second high-frequency equal-amplitude signal may be provided by a phase-locked loop of the clock generation module, and the local oscillator(s) (921 and/or 922) may be an internal oscillator of the phase-locked loop. For detailed descriptions of the clock generation module, please refer to related descriptions of the control unit 840, which will not be repeated here.

In some embodiments, the phase relationship between the first high-frequency equal-amplitude signal and the second high-frequency equal-amplitude signal may be determined by the analysis module. For detailed descriptions of the analysis module, please refer to the related descriptions of the control unit 840, which will not be repeated here.

The nonlinear element(s) (923 and/or 924) may be electronic components in which the relationship between electric current and voltage is non-linear. In some embodiments, the nonlinear element(s) (923 and/or 924) may mix the received signal with the output signal of the local oscillator(s) (921 and/or 922). Specifically, the nonlinear element 923 may mix the magnetic resonance spectrum signal (or the amplified magnetic resonance spectrum signal) output by the first receiving port 910 with the first high-frequency equal-amplitude signal output by the local oscillator 921 to generate a first frequency mixing signal. The nonlinear element 924 may mix the magnetic resonance spectrum signal (or the amplified magnetic resonance spectrum signal) output by the first receiving port 910 with the second high-frequency equal-amplitude signal output by the local oscillator 922 to generate a second frequency mixing signal. In some embodiments, the nonlinear element(s) (923 and/or 924) may include, but not limited to, a combination of one or more of diodes, triodes, and field effect transistors.

The bandpass filter(s) (925 and/or 926) may be electronic components that filter out the first signal and the second signal from the frequency mixing signal. In some embodiments, the bandpass filter(s) (925 and/or 926) may pass a signal with a target frequency in the frequency mixing signal, while attenuating a signal with other frequencies to a very low level, thereby filtering out the first signal and the second signal. Specifically, the bandpass filter 925 may filter out the first signal from the first frequency mixing signal, and the bandpass filter 926 may filter out the second signal from the second frequency mixing signal.

In some embodiments, the first high-frequency equal-amplitude signal and the second high-frequency equal-amplitude signal may be quadrature signals, and correspondingly, the first signal and the second signal may be quadrature signals.

Exemplarily, the frequency mixing circuit 920 may transform the amplified magnetic resonance spectrum signal with a frequency of 160 MHz into a first signal and a second signal with a frequency of 64 MHz.

In some embodiments of the present disclosure, the frequency mixing circuit 920 may be configured to make the frequency of the magnetic resonance spectrum signal meet the sampling clock frequency of the analog-to-digital converter, which improves the application range of the analog-to-digital converter.

The power divider 930 may be a component that divides the power of the magnetic resonance spectrum signal (or the first signal/second signal). In some embodiments, the power divider 930 may be configured to divide the magnetic resonance spectrum signal (or the first signal/second signal) into at least two power-divided signals.

A power-divided signal may be a magnetic resonance spectrum signal with a target power. In some embodiments, the target power may be determined based on the working power of the analog-to-digital converter. For detailed descriptions of the analog-to-digital converter, please refer to FIG. 10 and related descriptions thereof, which will not be repeated here.

In some embodiments, the power divider 930 may divide the first signal into at least two first power-divided signals and divide the second signal into at least two second power-divided signals.

In some embodiments, the power divider 930 may include a first power divider 931 and a second power divider 932. Specifically, the first power divider 931 may divide the first signal into at least two first power-divided signals, and the second power divider 932 may divide the second signal into at least two second power-divided signals. The first signal and the second signal may be quadrature signals, and correspondingly, each first power-divided signal and each second power-divided signal may be quadrature signals.

In some embodiments, the power(s) of the first power-divided signals (and/or the second power-divided signals) may be the same.

Exemplarily, the first power divider 931 may first divide a first signal with a power of 0 dBm into two signals with a power of −3 dBm, and then divide each of the two signals signal into two signals with a power of −6 dBm, so as to obtain 4 first power-divided signals with a power of −6 dBm. The 4 first power-divided signals may include a first power-divided signal 1, a first power-divided signal 2, . . . , and a first power-divided signal 4. Similarly, the second power divider may divide a second signal with a power of 0 dBm into 4 second power-divided signals with a power of −6 dBm. The 4 second power-divided signals may include a second power-divided signal 1, a second power-divided signal Sub-signal 2, . . . , and a second power-divided signal 4.

In some embodiments, the power(s) of the first power-divided signal (and/or the second power-divided signal) may be different.

Exemplarily, the first power divider 931 may first divide a first signal with a power of 0 dBm into two signals with a power of −3 dBm, and then divide each of the two signals into a signal with a power of −4 dBm and a signal with a power of −2 dBm, thereby obtaining 4 first power-divided signals. The 4 first power-divided signals may include a first power-divided signal 1 and a first power-divided signal 2 with a power of −4 dBm, a first power-divided signal 3 and a first power-divided signal 4 with a power of −2 dBm. Similarly, the second power divider may divide a second signal with a power of 0 dBm into 4 second power-divided signals. The 4 second power-divided signals may include a second power-divided signal 1 and a second power-divided signal 2 with a power of −4 dBm, a second power-divided signal 3 and a second power-divided signal 4 with a power of −2 dBm.

In some embodiments, each power-divided signal may be sent to one of the at least two analog-to-digital converters, so that each power-divided signal may be converted into a power-divided digital signal. The power-divided digital signals output by the at least two analog-to-digital converters may be configured to be added to obtain a digital output signal corresponding to the magnetic resonance spectrum signal. For detailed descriptions of obtaining the digital output signal corresponding to the magnetic resonance spectrum signal, please refer to FIG. 8 and related descriptions thereof, which will not be repeated here.

In some embodiments of the present disclosure, the power divider 930 may be configured to make the magnetic resonance spectrum signal suitable for the power of the analog-to-digital converter, so that a plurality of analog-to-digital converters can simultaneously process a plurality of magnetic resonance spectrum signals, improving the processing efficiency of the magnetic resonance spectrum signal. At the same time, the analog-to-digital converter can simultaneously process the magnetic resonance spectrum signal and the magnetic resonance imaging signal, thereby improving the application range of the analog-to-digital converter.

In some alternative embodiments, the bandpass filter in the frequency mixing circuit 920 and the power divider 930 may be replaced by a narrowband Wilkinson power divider. The narrowband Wilkinson power divider may realize a function of filtering and distributing signals from frequency mixing signals. In some embodiments of the present disclosure, functions of filtering and power division may be realized simultaneously based on the narrowband Wilkinson power divider, which can save hardware resources and optimize circuits.

Some embodiments of the present disclosure may use the frequency mixing circuit 920 to simulate an I/Q modulation and use the power divider 930 to divide the magnetic resonance signal into a plurality of power-divided signals (such as N power-divided signals) so that an amplitude of a synthesized signal obtained based on N power-divided digital signals converted through the analog-to-digital converter may be increased to N times, and a noise power in the synthesized signal may also be increased to N times. Therefore, an average amplitude of the noise in the synthesized signal may be increased to \sqrt{N} times, thereby reducing the influence of the noise generated by the analog-to-digital converter on the signal.

In some embodiments, the device 900 may be configured to be detachably connected with at least two analog-to-digital converters and a control unit. For example, the device 900 may be configured as a board including at least one socket, and the at least one socket may be inserted into the at least two analog-to-digital converters and the control unit. In some embodiments, each analog-to-digital converter may be configured to convert one of at least two first power-divided signals into a first power-divided digital signal or convert one of at least two second power-divided signals into a second power-divided digital signal. For detailed descriptions of the analog-to-digital converter, please refer to FIG. 8 and related descriptions thereof, which will not be repeated here. In some embodiments, the control unit may be configured to obtain the digital output signal corresponding to the magnetic resonance spectrum signal by respectively adding at least two first power-divided digital signals and at least two second power-divided digital signals. For detailed descriptions of the control unit, please refer to FIG. 10 and related descriptions thereof, which will not be repeated here.

FIG. 10 is a schematic diagram illustrating a control unit according to some embodiments of the present disclosure.

A control unit 840 may be a circuit for controlling a first signal-receiving unit 810, a second signal-receiving unit 820, and/or an analog-to-digital conversion unit 830.

As shown in FIG. 10, in some embodiments, the control unit 840 may include an analysis module 1010, a control module 1020, and a clock generation module 1030.

The analysis module 1010 may be configured to analyze host instructions. In some embodiments, the analysis module 1010 may receive and analyze the host instructions, and generate local control instructions and local operating parameters based on analyzed results.

The host instructions may be control instructions received from a host. In some embodiments, the host instructions may include but be not limited to task types, nuclide information, front-end receiving device parameters, magnetic resonance signal frequency, or the like.

In some embodiments, the task types may include spectral analysis tasks and imaging tasks. In some embodiments, the nuclide information may include nuclide types, such as a hydrogen nucleus or a hydrogen nucleus, a helium nucleus, a fluorine nucleus, and a phosphorus nucleus. In some embodiments, the front-end receiving device parameters may include a size of a magnetic field (B0) and a size of a radio frequency field (B1), or the like. In some embodiments, the magnetic resonance signal frequency may be divided into a relatively high frequency signal and a relatively low frequency signal based on a maximum bandwidth of the analog-to-digital converter. Specifically, if the magnetic resonance signal frequency is higher than the maximum bandwidth of the analog-to-digital converter, the magnetic resonance signal frequency may be a relatively high frequency; and if the magnetic resonance signal frequency is lower than or equal to the maximum bandwidth of the analog-to-digital converter, the magnetic resonance signal frequency may be a relatively low frequency.

The local control instructions may be instructions configured to control components and/or circuits in the first signal-receiving unit 810, the second signal-receiving unit 820, and/or the analog-to-digital conversion unit 830 generated by the analysis module based on the host instructions. In some embodiments, the local control instructions may include but be not limited to switch unit control instructions, power supply control instructions, signal processing control instructions, or the like. The switch unit control instructions may be instructions configured to start a switch unit control program. The signal processing control instructions may be instructions configured to start a signal processing control program. The power supply control instructions may be instructions configured to start a power supply control program.

The local operating parameters may be operating parameters of the components and/or circuits in the first signal-receiving unit 810, the second signal-receiving unit 820, and/or the analog-to-digital conversion unit 830 generated by the analysis module based on the host instructions. In some embodiments, the local operating parameters may include but be not limited to a phase relationship of high-frequency equal-amplitude signals, gain and/or attenuation values of a first amplification circuit, a second amplification circuit, and an amplifier, and filtering parameters of an anti-aliasing filter, or the like. More descriptions of the high-frequency equal-amplitude signals may be found in related descriptions of a mixing circuit 812, more descriptions of the first amplification circuit may be found in related descriptions of the first signal-receiving unit 810, and more descriptions of the second amplification circuit, the amplifier, and the anti-aliasing filter, may be found in related descriptions of the second signal-receiving unit 820, which may not be repeated herein.

For example, the analysis module may determine a signal processing control instruction “starting a first signal processing control program,” a switch unit control instruction “starting a switch unit control program A,” and a power supply control instruction “starting a first power supply control program” based on the “imaging task” and “nuclide type: hydrogen core” in a host instruction; further, the analysis module may determine the gain and/or attenuation value of the amplifier and the second amplification circuit and the filtering parameters of the anti-aliasing filter based on the “front-end receiving device parameters” and “nuclide type: hydrogen core” in the host instruction.

As another example, the analysis module may determine a signal processing control instruction “starting a second signal processing control program,” a switch unit control instruction “starting a switch unit control program B,” and a power supply control instruction “start a second power supply control program” based on the “spectrum analysis task,” “nuclide types: hydrogen nucleus, helium nucleus, fluorine nucleus, and phosphorus nucleus,” and the magnetic resonance signal frequency “a relatively high frequency” in the host instruction; further, the analysis module may determine the gain and/or attenuation values of the first amplification circuit and the second amplification circuit, the filtering parameters of the anti-aliasing filter, and the phase relationship of the high-frequency equal-amplitude signal based on the “front-end receiving device parameters” and “nuclide types: hydrogen nucleus, helium nucleus, fluorine nucleus, and phosphorus nucleus” in the host instruction.

As a further example, the analysis module may determine a signal processing control instruction “starting a third signal processing control program,” a switch unit control instruction “starting a switch unit control program B,” and a power supply control instruction “starting a second power supply control program” based on the “imaging analysis task,” “nuclide types: hydrogen nucleus, helium nucleus, fluorine nucleus, and phosphorus nucleus,” and the magnetic resonance signal frequency “a relatively high frequency” in the host instruction; further, the analysis module may determine the gain and/or attenuation values of the first amplification circuit and the second amplification circuit, the filtering parameters of the anti-aliasing filter, and the phase relationship of the high-frequency equal-amplitude signal based on the “front-end receiving device parameters” and “nuclide types: hydrogen nucleus, helium nucleus, fluorine nucleus, and phosphorus nucleus” in the host instruction.

As a further example, the analysis module may determine a signal processing control instruction “starting a fourth signal processing control program,” a switch unit control instruction “starting a switch unit control program C,” and a power supply control instruction “starting a third power supply control program” based on the “spectrum analysis task,” “nuclide type: nitrogen nucleus,” and the magnetic resonance signal frequency “a relatively low frequency” in the host instruction; further, the analysis module may determine the gain and/or attenuation values of the first amplification circuit and the second amplification circuit, the filtering parameters of the anti-aliasing filter, and the phase relationship of the high-frequency equal-amplitude signal based on the “front-end receiving device parameters” and “nuclide type: nitrogen nucleus” in the host instruction.

As a further example, the analysis module may determine a signal processing control instruction “starting a fifth signal processing control program,” a switch unit control instruction “starting a switch unit control program C,” and a power supply control instruction “starting a third power supply control program” based on the “imaging analysis task,” “nuclide type: nitrogen nucleus,” and the magnetic resonance signal frequency “a relatively low frequency” in the host instruction; further, the analysis module may determine the gain and/or attenuation values of the first amplification circuit and the second amplification circuit, the filtering parameters of the anti-aliasing filter, and the phase relationship of the high-frequency equal-amplitude signal based on the “front-end receiving device parameters” and “nuclide type: nitrogen nucleus” in the host instruction.

More descriptions of the first signal processing control program, the second signal processing control program, the third signal processing control program, the fourth signal processing control program, the fifth signal processing control program, the first power supply control program, the second power supply control program, and the third power supply control program may be found in related descriptions of the control module, which may not be repeated herein.

More descriptions of the switch unit control program A and the switch unit control program B may be found in FIG. 11 and related descriptions, which may not be repeated herein.

In some embodiments, the analysis module may instruct the control module to start a corresponding control program by sending a local control instruction to the control module.

In some embodiments, the analysis module may send local operating parameters to various components and/or circuits.

The control module 1020 may be a module for controlling the components and/or circuits in the first signal-receiving unit 810, the second signal-receiving unit 820, and/or the analog-to-digital conversion unit 830. In some embodiments, the control module 1020 may include but is not limited to a field-programmable gate array (FPGA), a complex programmable logic device (CPLD), a microcontroller unit (MCU), a central processing unit (CPU), a graphics processing unit (GPU), or the like, or any combination thereof.

For example, the control module 1020 may be an integrated circuit of FPGA, including a logic gate circuit, a register, a hard-core multiplier and adder, a random access memory, or the like.

In some embodiments, the control module 1020 may include switch unit control programs, power supply control programs, and signal processing control programs.

The switch unit control programs may be programs configured to control switching on and/or off of a switch unit in the magnetic resonance signal processing device 800. In some embodiments, the switch unit control programs may control a first switch unit, a second switch unit, and/or a third switch unit based on the switch unit control instructions. In some embodiments, the switch unit control programs may include the switch unit control program A, the switch unit control program B, and the switch control unit program C. More descriptions of the switch unit control programs may be found in FIG. 11 and related descriptions, which may not be repeated herein.

The power supply control programs may be programs configured to control the power supply and/or power off of the components and/or circuits in the first signal-receiving unit 810, the second signal-receiving unit 820, and/or the analog-to-digital conversion unit 830. In some embodiments, the power supply control programs may include the first power supply control program, the second power supply control program, and the third power supply control program.

The first power supply control program may be a program configured to supply power to components and/or circuits that process magnetic resonance spectrum signals with relatively high frequencies. In some embodiments, the first power supply control program may include: powering off a first amplification circuit and powering on amplifiers of all receiving channels and second amplification circuits of all receiving channels.

The second power supply control program may be a program configured to supply power to the components and/or circuits that process magnetic resonance imaging signals. In some embodiments, the second power supply control program may include: powering off the amplifier and powering on the first amplification circuits and the second amplification circuits of all receiving channels.

The third power supply program may be a program configured to supply power to the components and/or circuits that process magnetic resonance spectrum signals with relatively low frequencies. In some embodiments, the third power supply control program may include: powering off the first amplification circuit, powering on the amplifier and the second amplification circuit of a receiving channel corresponding to a target receiving port, and powering off the amplifiers and the second amplification circuits of rest receiving channels. More descriptions of the target receiving port may be found in FIG. 11 and related descriptions, which may not be repeated herein.

The signal processing control program may be a program for processing imaging digital signals and/or spectral digital signals. In some embodiments, the signal processing control program may include the first signal processing control program, the second signal processing control program, the third signal processing control program, the fourth signal processing control program, and the fifth signal processing control program.

The first signal processing control program may be a program configured to generate K-space data based on the imaging digital signals. In some embodiments, the first signal processing control program may include a conversion operation. In some embodiments, the conversion operation may obtain the K-space data corresponding to the nuclide as a digital output signal by filling imaging digital signals corresponding to the nuclide (e.g., hydrogen nucleus or multi-nucleus) into the K-space.

The second signal processing control program may be a program configured to generate a spectrogram of chemical shift values based on at least two power-divided digital signals corresponding to various atomic nuclei. More descriptions of the chemical shift values may be found in FIG. 9 and related descriptions, which may not be repeated herein. In some embodiments, the second signal processing control program may include a synthesis operation and a spectrum generation operation. In some embodiments, the synthesis operation may be performed by adding power-divided digital signals (e.g., a first power-divided digital signal and/or a second power-divided digital signal) to obtain a synthetic signal corresponding to magnetic resonance spectrum signals of the various atomic nuclei. For example, the synthesis operation may be performed by adding a first power-divided digital signal-1, a first power-divided digital signal-2, . . . , a first power-divided digital signal-n, a second power-divided digital signal-1, . . . , a second power-divided digital signal-n to obtain a synthetic signal corresponding to magnetic resonance imaging signals of the various atomic nuclei. In some embodiments, the spectrogram generation operation may obtain a spectrogram of the chemical shift values as a digital output signal by generating the chemical shift values based on the synthetic signal.

The third signal processing control program may generate a K-space data program based on the power-divided signals corresponding to the various atomic nuclei. In some embodiments, the third signal processing control program may include a synthesis operation and a conversion operation. In some embodiments, the synthesis operation may be performed by adding the power-divided digital signals (e.g., the first power-divided digital signal and/or the second power-divided digital signal) to obtain the synthetic signal corresponding to the magnetic resonance spectrum signals of the various atomic nuclei. In some embodiments, the conversion operation may obtain the K-space data corresponding to the various atomic nuclei as the digital output signal by filling the synthetic signal corresponding to various atomic nuclei into the K-space.

The fourth signal processing control program may be a program configured to generate a spectrogram of the chemical shift values based on digital signals corresponding to one or more atomic nuclei. More descriptions of the chemical shift values may be found in FIG. 9 and related descriptions, which may not be repeated herein. In some embodiments, the fourth signal processing control program may include a spectrogram generation operation. In some embodiments, the spectrogram generation operation may obtain a spectrogram of the chemical shift values as the digital output signal by generating the chemical shift values based on the spectral digital signals.

The fifth signal processing control program may generate a K-space data program based on the spectral digital signals corresponding to the one or more atomic nuclei. In some embodiments, the third signal processing control program may include a conversion operation. In some embodiments, the conversion operation may obtain the K-space data corresponding to the atomic nucleus as the digital output signal by filling the digital signals corresponding to the atomic nucleus into the K-space.

The clock generation module 1030 may provide operating frequencies and/or signals for the components and/or circuits of the first signal-receiving unit 810, the second signal-receiving unit 820, and/or the analog-to-digital conversion unit 830.

In some embodiments, the clock generation module 1030 may generate a signal with a specific frequency based on a phase locked loop (PLL). The PLL is a negative feedback control system that uses a voltage generated by phase synchronization to tune a voltage controlled oscillator (VCO) to generate a specific frequency. In some embodiments, the PLL may include a phase detector, a low-pass filter, a voltage-controlled oscillator, or the like. Specifically, the PLL may detect a phase difference between an input signal and an output signal using a phase detector, and convert the detected phase difference signal into a voltage signal, then a low-pass filter may be used to filter the voltage signal and input the voltage signal as a control voltage into the VCO, so as to control a frequency of an output signal of the VCO.

In some embodiments, the clock generation module 1030 may provide a first high-frequency equal-amplitude signal and/or a second high-frequency equal-amplitude signal for a frequency mixing circuit 920. Specifically, the clock generation module may designate an output signal of the VCO as the first high-frequency equal-amplitude signal and/or the second high-frequency constant amplitude signal. More descriptions of the first high-frequency equal-amplitude signal and/or the second high-frequency equal-amplitude signal may be found in the frequency mixing circuit 920, which may not be repeated herein.

In some embodiments, further, the clock generation module 1030 may provide operating frequencies for the analog-to-digital converter and/or the programmable logic device based on a frequency divider. Specifically, the clock generation module may divide frequency of the output signal of the VCO into the operating frequencies required by the analog-to-digital converter and/or programmable logic device by using the frequency divider.

Some embodiments of the present disclosure may use the clock generation module to configure operating frequencies for circuits and use a digital attenuator to configure different gains for magnetic resonance signal amplitudes, both the clock generation module and the digital attenuator may be flexibly configured for different nuclides, so as to achieve a relatively better match between the circuit gain and operating frequency, and ensure a high dynamic range and high signal-to-noise ratio.

FIG. 11 is an exemplary schematic diagram illustrating switch units according to some embodiments of the present disclosure. The switch units may be used to control a connection between the first signal-receiving unit 810, the second signal-receiving unit 820, and/or the analog-to-digital conversion unit 830 and/or a connection between internal circuits of each device. In some embodiments, the switch units may control circuit connections of the first signal-receiving unit 810, the second signal-receiving unit 820, and/or the analog-digital conversion unit 830, so that the first signal-receiving unit 810, the second signal-receiving unit 820, and/or the analog-digital conversion unit 830 may execute different processing programs, thus realizing different functions.

As shown in FIG. 11, the switch units may include a first switch unit, a second switch unit, and a third switch unit.

The first switch unit may be a unit for connecting or disconnecting A path between the analog-to-digital conversion unit 830 and the first signal-receiving unit 810.

In some embodiments, the first switch unit may include at least two first switches. In some embodiments, a first switch may connect an output circuit of a power divider 116 of the first signal-receiving unit 810 with the analog-to-digital conversion unit 830 to input the power-divided signal into the analog-to-digital converter. In some embodiments, the first switches may input the magnetic resonance imaging signal into the analog-to-digital converter by connecting a second receiving port with a corresponding analog-to-digital converter. In some embodiments, the first switches may be a single-pole double-throw switch for connecting or disconnecting the path between the analog-to-digital conversion unit 830 and the first signal-receiving unit 810 and a path between the analog-to-digital conversion unit 830 and the second signal-receiving unit 820. In some embodiments, the first switches may include a single-pole single-throw switch for connecting or disconnecting the path between the analog-to-digital conversion unit 830 and the first signal-receiving unit 810.

As shown in FIG. 11, when a first switch-1, a first switch-2, . . . , and a first switch-2n is switched up, the power divider 116 of the first signal-receiving unit 810 may be connected with an analog-digital converter-1, an analog-digital converter-2, . . . , and an analog-digital converter-2n, so that a first power-divided signal-1 (not shown in the figures), a first power-divided signal-2 (not shown in the figures), . . . , and a second power-divided signal-n may be input into the analog-to-digital converter-1, the analog-to-digital converter-2, . . . , and the analog-to-digital converter-2n, respectively; when a first switch-1, a first switch-2, . . . , and a first switch-2n is switched down, a second receiving port-1, a second receiving port-2, . . . , and a second receiving port-2n may be connected with the analog-to-digital converter-1, the analog-to-digital converter-2, . . . , and the analog-to-digital converter-2n, respectively, so that a magnetic resonance imaging signal-1 (not shown in the figures), a magnetic resonance imaging signal-2 (not shown in the figures), . . . , a magnetic resonance imaging signal-2n (not shown in the figures) may be input into the analog-to-digital converter-1, the analog-to-digital converter-2, . . . , and the analog-to-digital converter-2n, respectively.

In some embodiments, part of the analog-to-digital converters may be configured to be merely connected with the second receiving port or/or the first signal-receiving unit 810, accordingly, the first switches may be replaced by a path merely connected with the second receiving port or/or the first signal-receiving unit 810.

In some embodiments, an attenuator may be arranged between each first switch and an amplifier. In some embodiments, when a first switch inputs a power-divided signal into an analog-to-digital converter, the attenuator may provide attenuation for the power-divided signal, so as to ensure that a signal output after the subsequent second amplification circuit gains the power-divided signal is not compressed and not overflow a dynamic range of the analog-to-digital converter while taking into account a relatively high signal-to-noise ratio. In some embodiments, the attenuator may be a fixed attenuator, a variable attenuator, a digital attenuator, or the like, or any combination thereof.

The second switch unit may be a unit configured to control an output flow direction of a target receiving port. In some embodiments, the second switch unit may be used to connect or disconnect a path between the target receiving port and the first signal-receiving unit 810.

The target receiving port may be a port configured to receive magnetic resonance spectrum signals. In some embodiments, at least one of the at least two receiving ports may be designated as the target receiving port. For example, as shown in FIG. 11, if the second receiving port-1 is designated as the target receiving port, the second receiving port-1 may receive the magnetic resonance spectrum signals.

It can be understood that when a second receiving port of the second signal-receiving unit is designated as the target receiving port for receiving the spectral magnetic resonance signals, the target receiving port may be used to receive both the magnetic resonance imaging signals and the spectral magnetic resonance signals.

In some embodiments, when at least one of the second receiving port of the second signal-receiving unit is designated as the target receiving port for receiving the magnetic resonance spectrum signal, the first receiving port may be reserved or omitted.

In some embodiments, the second switch unit may include at least one second switch.

In some embodiments, a second switch may be a single-pole double-throw switch. In some embodiments, when the target receiving port receives the magnetic resonance spectrum signals, the second switch may connect the target receiving port with the first signal-receiving unit 810, thus the received magnetic resonance spectrum signals may be output to the first signal-receiving unit 810 for processing. In some embodiments, when the target receiving port receives the magnetic resonance imaging signals, the second switch may connect the target receiving port with the second signal-receiving unit 820, thus the magnetic resonance imaging signals may be input into the second signal-receiving unit 820 for processing.

As shown in FIG. 11, when the target receiving port “second receiving port-1” receives the magnetic resonance spectrum signals, a second switch-1 may be switched up, the second receiving port-1 may be connected with the first signal-receiving unit 810, and the second receiving port-1 may be disconnected with a receiving channel-1 (not shown in the figures), so that the magnetic resonance spectrum signals may be transmitted to the first signal-receiving unit 810 through the second receiving port-1; when the target receiving port “second receiving port-1” receives the magnetic resonance imaging signals, the second switch-1 may be switched down, the second receiving port-1 may be disconnected with the first signal-receiving unit 810, and the second receiving port-1 may be connected with a channel (i.e., the receiving channel-1) for receiving the magnetic resonance imaging signal-1 (not shown in the figures), so that the magnetic resonance imaging signal-1 (not shown in the figures) may be transmitted to the second signal-receiving unit 820 through the second receiving port-1.

In some embodiments, the second switch unit may also connect second switches other than the target receiving port with the corresponding receiving channels, to input the magnetic resonance imaging signals received by the other second switches into the second signal-receiving unit 820 for processing.

In some embodiments, the second switch unit may merely include a second switch corresponding to a fixed target receiving port, which may be used to output the magnetic resonance spectrum signals received by the target receiving port to the first signal-receiving unit 810. One of the received magnetic resonance imaging signals may output to a processing channel corresponding to the second signal-receiving unit 820, and the other second switches other than the target receiving port may be replaced by paths, so that the other second receiving ports may remain connected with the corresponding processing channels.

Continuing with the above example, as shown in FIG. 11, when the target receiving port “second receiving port-1” receives the magnetic resonance imaging signals, and the second switch-1 is switched down, the “second receiving port-2,” . . . , and “second receiving port-2n” may also receive the magnetic resonance imaging signal-2 (not shown in the figures), . . . , and the magnetic resonance imaging signal-2n (not shown in the figures), and the second switch-2, . . . , the second switch-2n is switched down, so that the magnetic resonance imaging signal-2 (not shown in the figures), . . . , and the magnetic resonance imaging signal-2n (not shown in the figures) may be transmitted to the second signal-receiving unit 820.

In some embodiments, a second switch may be a single-pole single-throw switch. In some embodiments, when the second switch is turned off, the target receiving port may be connected with the first signal-receiving unit 810 to output the received magnetic resonance spectrum signal to the first signal-receiving unit 810 for processing.

The third switch unit may be a unit for connecting or disconnecting the at least two receiving channels.

In some embodiments, the third switch unit may include at least one third switch. In some embodiments, a third switch may be a single-pole single-throw switch. In some embodiments, when the third switch is turned off, the second receiving port may input the received magnetic resonance imaging signals into the analog-to-digital converter. As shown in FIG. 11, when a third switch-1 is turned off, the second receiving port-1 may input the received magnetic resonance imaging signal-1 (not shown in the figures) into the analog-to-digital converter-1.

In some embodiments, the third switch unit may also be used to connect or disconnect other receiving channels. As shown in FIG. 11, when a third switch-2, . . . , and a third switch-2n are turned off, the second receiving port-2, . . . , and the second receiving port-2n may input the received magnetic resonance imaging signal-2 (not shown in the figures), . . . , and the magnetic resonance imaging signal-2n (not shown in the figures) into the analog-to-digital converter-2, . . . , and the analog-to-digital converter-2n, respectively.

In some embodiments, the switch unites may control an outflow direction of the target receiving port based on the second switch of the single-pole double-throw to input the magnetic resonance spectrum signals into the first signal-receiving unit 810, or input the magnetic resonance imaging signals into the second signal-receiving unit 820. In some alternative embodiments, the receiving channels corresponding to the second receiving ports other than the target receiving port may replace the third switch with transmission paths to keep the other second receiving ports connected with the corresponding receiving channels.

In some embodiments, the target receiving port may be connected with the first signal-receiving unit 810 based on a second switch of single-pole single-throw, so as to the magnetic resonance spectrum signals into the first signal-receiving unit 810; a third switch may connect the receiving channel based on the single-pole single-throw, so as to input the magnetic resonance imaging signals into the corresponding receiving channel. In some embodiments, the switch unit control program may start the switch unit control program based on the switch unit control instructions to control the first switch unit, the second switch unit, and the third switch unit. As mentioned above, in some embodiments, the switch unit control program may include the switch unit control program A, the switch unit control program B, and the switching unit control degree C.

In some embodiments, a third switch may be omitted. For example, when a first switch corresponding to the receiving channel is a single-pole double-throw switch, the first switch may be used to connect or disconnect a path between the analog-to-digital converter and the first signal-receiving unit 810 and may be used to connect or disconnect the receiving channel, at this time, a third switch corresponding to the receiving channel may be omitted. As another example, when a second switch corresponding to the receiving channel is a single-pole double-throw switch, the second switch may be used to connect or disconnect a path between the target receiving port and the first signal-receiving unit 810 and may be used to connect or disconnect a receiving channel corresponding to the target receiving port, at this time, a third switch corresponding to the receiving channel may be omitted.

In some embodiments of the present disclosure, the target receiving port may receive the magnetic resonance spectrum signals or magnetic resonance imaging signals, which improves the dynamic range of the circuit and saves circuit resources.

The switch unit control program A may be a switch unit control program configured to process the magnetic resonance imaging signals. In some embodiments, the switch unit control program A may include: the second switching unit connecting the target receiving port and/or the second receiving port with a corresponding receiving channel, the third switch unit connecting the receiving channels corresponding to the target receiving port, and/or the second receiving port, and the first switch unit connecting the second receiving port with the corresponding analog-to-digital converter.

For example, as shown in FIG. 11, the switch unit control program A may include: switching down the second switch-1 of the target receiving port “second receive port-1,” the second switches-2, . . . , the second switches-2n of other second receive ports; turning on the third switch-1 of the target receiving port “second receive port-1,” the third switches-2, . . . , and the third switches-2n of other second receive ports; switching down the first switch-1, the first switch-2, . . . , and the first switch-2n of the first switch unit.

The switch unit control program B may be a switch unit control program configured to process magnetic resonance spectrum signals with relatively high frequencies. In some embodiments, the switch unit control program B may include: the second switch unit connecting the target receiving port with the first signal-receiving unit, the third switch unit disconnecting the receiving channel corresponding to the target receiving port, and the first switch unit connecting an output circuit of the power divider of the first signal-receiving unit 810 with the analog-to-digital converter.

For example, as shown in FIG. 11, the switch unit control program B may include: switching up the second switch-1 of the target receiving port “the second receiving port-1”; turning off the third switch-1; and switching up the first switch-1, the first switch-2, . . . , and the first switch-2n.

The switch unit control program C may be a switch unit control program configured to process magnetic resonance spectrum signals with relatively low frequencies. As set forth above, when at least one second receiving port of the second signal-receiving unit is designated as the target receiving port for receiving the magnetic resonance spectrum signals, the first receiving port may be omitted. Accordingly, in some embodiments, the switch unit control program C may include: the second switch unit connecting the target receiving port with a corresponding receiving channel, the third switch unit connecting the receiving channel corresponding with the target receiving port, and the first switch unit connecting the target receiving port to a corresponding analog-to-digital converter.

For example, as shown in FIG. 11, the target receiving port “the second receiving port-1” may be regarded as a first receiving port of the first signal-receiving unit 810, which may be used to receive the magnetic resonance spectrum signals with relatively low frequencies, the switch unit control program C may include: switching down the second switch-1 of the target receiving port “the second receiving port-1”; turning on the third switch-1; switching down the third switch-1; and turning off other switches.

Some embodiments of the present disclosure may change the magnetic resonance signals received by the first receiving port and/or the second receiving port by using the first switch unit, the second switch unit, and the third switch unit to achieve different uses of the same port, thus saving hardware resource costs.

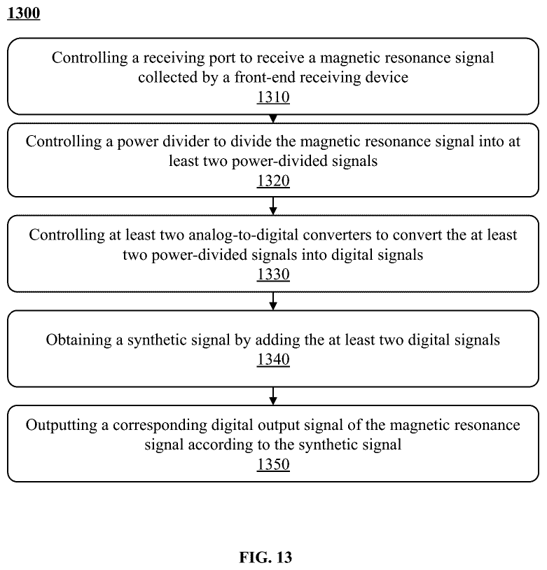

In some embodiments, the first signal-receiving unit 810 may be a separate processing device to process the magnetic resonance spectrum signals. In some embodiments, the first signal-receiving unit 810 may further include an analog-to-digital converter for performing analog-to-digital conversion on the power-divided signal. More descriptions of the analog-to-digital converter may be found in FIG. 10 and related descriptions, which may not be repeated herein. In some embodiments, the first signal-receiving unit 810 may further include a control unit configured to control the first signal-receiving unit 810 to process the magnetic resonance spectrum signal, for example, the first receiving port may be controlled to receive the magnetic resonance signal collected by the front-end receiving device; the power divider may be controlled to divide the magnetic resonance spectrum signal into at least two power-divided signals; the at least two analog-to-digital converters may be controlled to convert the at least two power-divided signals into the digital signals; a synthetic signal may be obtained by adding the at least two digital signals; according to the synthetic signal, a corresponding digital output signal of the magnetic resonance spectrum signal may be output. More descriptions of the control unit may be found in FIG. 13 and related descriptions, which may not be repeated herein.

In some embodiments, the one or more first signal-receiving units 810 may be configured to realize parallel acquisition of the nuclides. For example, four first signal-receiving units 810 may be configured to realize the application of 4-channels ¹³C coil. As another example, the four first signal-receiving units 810 may be configured to realize the parallel acquisition based on four nuclides ¹⁵N, ¹H, ²H, and ¹³C, each of which may correspond to a channel (i.e., corresponding to a first signal-receiving unit 810).

FIG. 13 is a flowchart illustrating an exemplary process according to some embodiments of the present disclosure. Specifically, FIG. 13 may be executed by the control unit 840. As shown in FIG. 13, process 1300 may include one or more of the following operations:

In 1310, the receiving port may be controlled to receive a magnetic resonance signal collected by a front-end receiving device.

As mentioned above, the front-end receiving device may be a device configured to receive a magnetic resonance signal (or the magnetic resonance signal) in the magnetic resonance device. More descriptions of the front-end receiving device may be found in FIG. 8 and related descriptions, which may not be repeated herein.

In some embodiments, the magnetic resonance signal may include a magnetic resonance imaging signal or a magnetic resonance spectrum signal.

In some embodiments, when the magnetic resonance signal is the magnetic resonance imaging signal, the control unit 840 may determine that the receiving port is a second receiving port of the second signal-receiving unit 820.

In some embodiments, when the magnetic resonance signal is the magnetic resonance spectrum signal, the control unit 840 may determine that the receiving port is a first receiving port of the first signal-receiving unit 810, or a second receiving port designated as the target receiving port in the second signal-receiving unit 820.

In 1320, the power divider may be controlled to divide the magnetic resonance signal into at least two power-divided signals.

In some embodiments, the control unit 840 may control the power divider to divide the magnetic resonance spectrum signal into the at least two power-divided signals. More descriptions of the power divider may be found in FIG. 9 and related descriptions, which may not be repeated herein.

In 1330, the analog-to-digital converter may be controlled to convert the imaging spectrum signal, the radio frequency spectrum signal, or the at least two power-divided signals into digital signals.

In some embodiments, the digital signals may include an imaging digital signal, a radio frequency digital signal, or a power-divided digital signal.

In some embodiments, the control unit 840 may control the at least two analog-to-digital converters to convert the imaging spectrum signal into the imaging digital signal.

In some embodiments, the control unit 840 may control the analog-to-digital converter to convert the magnetic resonance spectrum signal into the spectrum digital signal.

In some embodiments, the control unit 840 may control the at least two analog-to-digital converters to convert the at least two power-divided signals into the at least two power-divided digital signals.

More descriptions of the analog-to-digital converter may be found in FIG. 8 and related descriptions, which may not be repeated herein.

In some embodiments, the control unit may further obtain K-space data according to the imaging digital signal.

In 1340, a synthetic signal may be obtained by adding the at least two digital signals.

In some embodiments, the synthetic signal may be a synthetic signal corresponding to the magnetic resonance spectrum signal. In some embodiments, the control unit 840 may obtain the synthetic signal corresponding to the spectrum radio frequency by adding the at least two power-divided digital signals.

More descriptions of the synthetic signal may be found in FIG. 10 and related descriptions, which may not be repeated herein.

In 1350, a corresponding digital output signal of the magnetic resonance signal may be output according to the synthetic signal or the spectrum digital signal.

In some embodiments, the digital output signal may be the spectrogram of the chemical shift values or the K-space data corresponding to the spectral magnetic resonance signal.

More descriptions of the digital output signal corresponding to the output magnetic resonance signal may be found in FIG. 10 and related descriptions, which may not be repeated herein.

In some embodiments, the control unit 840 may perform one or more operations in FIG. 13 based on different magnetic resonance signals, and the local control instructions may be generated based on the host instructions according to the analysis module 1010.

In some embodiments, when the magnetic resonance signal is the magnetic resonance imaging signal, the control unit 840 may perform operations 1310 and 1330.

For example, the control unit 840 may start the “switch unit control program A,” the “switch unit control program A” may control the target receiving port in the second receiving port to disconnect from the first signal-receiving unit 810, so that the magnetic resonance imaging signal may be input from the second receiving port to the second signal-receiving unit 820 (i.e., the operation 1310); further, the third switch unit may be connected with the receiving channel corresponding to the second receiving port, and the first switch unit may disconnect the first signal-receiving unit 810 from the analog-to-digital conversion unit 830, so that the magnetic resonance imaging signal may be input to the corresponding analog-to-digital converter in the analog-to-digital conversion unit 830, and the imaging digital signal may be output. Then the control unit 840 may start the “first signal processing control program” based on the “imaging task,” and generate the K-space data corresponding to the magnetic resonance imaging signal by filling the imaging digital signal into the K-space, (i.e., the operation 1330).

In some embodiments, when the magnetic resonance signal is the magnetic resonance spectrum signal with a relatively high frequency, the host instructions may include a “spectrum analysis task,” and the control unit 840 may perform operations 1310 to 1350.

For example, the control unit may start the “switch unit control program B,” the “switch unit control program B” may control the second switch unit to connect the target receiving port in the second receiving port with the first signal-receiving unit 810, so that the magnetic resonance spectrum signal may be input to the first signal-receiving unit 810 (i.e., the operation 1310); further, the first signal-receiving unit 810 may use the power divider to divide the magnetic resonance signal into the at least two power-divided signals (i.e., the operation 1320); further, “switch unit control program B” may control the third switch unit to disconnect the receiving channel and the first switch unit to connect the output circuit of the power divider of the first signal-receiving unit 810 with the analog-digital converter to output the power-divided digital signal (i.e., the operation 1330); the control unit 840 may start the “second signal processing control program” based on the “spectrum analysis task” and “relatively high frequency” to obtain the synthetic signal by synthetizing the power-divided digital signals (i.e., the operation 1340), the control unit 840 may generate a digital output signal according to the synthetic signal (i.e., the operation 1350), and the digital output signal may be sent to the processor (e.g., an upper computer) for the spectrum analysis. It can be understood that when the frequency of the magnetic resonance spectrum signal is relatively high, the power division may be performed on the magnetic resonance spectrum signal, so that the frequency of the power-divided signal obtained based on the magnetic resonance spectrum signal may be applicable to a sampling clock frequency of the analog-to-digital converter.

In some embodiments, when the magnetic resonance signal is a magnetic resonance spectrum signal with a relatively high frequency, the host instructions may include an “imaging task,” and the control unit 840 may execute the operations 1310, 1320, and 1330.

For example, the control unit may start “switch unit control program B,” and “switch unit control program B” may control the second switch unit to connect the target receiving port in the second receiving port with the first signal-receiving unit 810, so that the magnetic resonance spectrum signal may be input to the first signal-receiving unit 810 (i.e., the operation 1310); further, the first signal-receiving unit 810 may use the power divider to divide the magnetic resonance signal into the at least two power-divided signals (i.e., the operation 1320); further, “switch unit control program B” may control the third switch unit to disconnect the receiving channel and the first switch unit to connect the output circuit of the power divider of the first signal-receiving unit 810 with the analog-to-digital converter to output the power-divided digital signal, the control unit 840 may start the “third signal processing control program” based on the “imaging task” and “relatively high frequency” to obtain the synthetic signal corresponding to multiple atomic nuclei by adding the power-divided digital signal (i.e., the first power-divided digital signal and/or the second power-divided digital signal), and the control unit 840 may fill the synthesized signal corresponding to various atomic nuclei into the K-space, and obtain the K-space data corresponding to the various atomic nuclei (i.e., the operation 1330).

In some embodiments, when the magnetic resonance signal is a magnetic resonance spectrum signal with a relatively low frequency, the host instructions may include a “spectrum analysis task,” and the control unit 840 may execute the operations 1310, 1330, and 1350.

For example, the control unit may start the “switch unit control program C,” and the “switch unit control program C” may control the second switch unit to connect the target receiving port in the second receiving port with the receiving channel, so that the magnetic resonance spectrum signal may be input into the receiving channel (i.e., the operation 1310); further, “switch unit control program C” may control a connection of the third switch unit, control the first switch unit to connect the receiving channel with a corresponding analog-to-digital converter, so that the magnetic resonance spectrum signal may be input into the analog-to-digital converter of one of the receiving channels through the target receiving port, and output the spectrum digital signal (i.e., the operation 1330); the control unit 840 may start the “fourth signal processing control program” based on the “spectrum analysis task” and “relatively low frequency” to generate a digital output signal (i.e., the operation 1350), and the digital output signal may be sent to the processor (e.g., the upper computer) for the spectrum analysis. It can be understood that when the frequency of the magnetic resonance spectrum signal is relatively low, the magnetic resonance spectrum signal does not need to perform the power division, and the magnetic resonance spectrum signal may be applied to the sampling clock frequency of the analog-to-digital converter.

In some embodiments, when the magnetic resonance signal is a magnetic resonance spectrum signal with a relatively low frequency, the host instruction may include an “imaging task,” and the control unit 840 may execute operations 1310 and 1330.

For example, the control unit may start the “switch unit control program C,” and the “switch unit control program C” may control the second switch unit to connect the target receiving port in the second receiving port with the receiving channel, so that the magnetic resonance spectrum signal may be input into the receiving channel (i.e., the operation 1310); further, the “switch unit control program C” may control a connection of the third switch unit, control the first switch unit to connect the receiving channel with the corresponding analog-to-digital converter, so that the magnetic resonance spectrum signal may be input into the analog-to-digital converter of one of the receiving channels through the target receiving port, and output the spectrum digital signal; the control unit 840 may start the “fifth signal processing control program” based on the “spectrum analysis task” and “relatively low frequency,” fill the spectrum digital signal into the K-space, and obtain the K-space data corresponding to the various atomic nucleus (i.e., the operation 1330).

It should be noted that the above descriptions are provided for illustrative purposes only and are not intended to limit the scope of the present disclosure. For those skilled in the art, many changes and modifications can be made under the guidance of the content of the present disclosure. However, these changes and modifications may not deviate from the scope of the present disclosure.

The possible beneficial effects of the embodiments of the present disclosure may include but may not be limited to: (1) the first signal-receiving unit ues a power divider to divide the magnetic resonance spectrum signal into a plurality of power-divided signals, so that a plurality of analog-to-digital converters in an analog-to-digital conversion unit may process the magnetic resonance imaging signal received by the second signal-receiving unit, and also take into account a relatively high dynamic range and a relatively high signal-to-noise ratio when processing the plurality of power-divided signals, thereby improving an utilization rate of the analog-to-digital conversion unit; (2) the mixing circuit is used to convert the frequency of the magnetic resonance spectrum signal to an operating frequency of components in the second receiving signal-receiving unit, so that the second amplification circuit and the analog-to-digital converter in the second receiving signal-receiving unit may be used to process the magnetic resonance spectrum signal and the magnetic resonance imaging signal at the same time, expanding the role of the components and saving the cost of hardware resources; (3) the magnetic resonance signal processing device is detachably connected with the at least two analog-digital converters and control units, so that the analog-digital converter and control unit may freely switch between magnetic resonance imaging and spectrum analysis; (4) the first switch unit, the second switch unit, and the third switch unit are used to change the magnetic resonance signal received by the first receiving port and/or the second receiving port, which can realize different uses of the same port, integrate hardware resources, and save hardware resource costs. It should be noted that different embodiments may produce different beneficial effects. In different embodiments, the beneficial effects may be any one or a combination of the above, or any other beneficial effects that may be obtained.

The basic concept has been described above, obviously, for those skilled in the art, the above detailed disclosure is only an example, and does not constitute a limitation to this description. Although not explicitly stated here, those skilled in the art may make various modifications, improvements and corrections to this description. Such modifications, improvements and corrections are suggested in the present disclosure, so such modifications, improvements and corrections still belong to the spirit and scope of the exemplary embodiments of the present disclosure.

Meanwhile, the present disclosure uses specific words to describe the embodiments of the present disclosure. For example, “one embodiment”, “an embodiment”, and/or “some embodiments” refer to a certain feature, structure or characteristic related to at least one embodiment of the present disclosure. Therefore, it should be emphasized and noted that two or more references to “an embodiment” or “an embodiment” or “an alternative embodiment” in different places in the present disclosure do not necessarily refer to the same embodiment. In addition, certain features, structures or characteristics in one or more embodiments of the present disclosure may be properly combined.

In addition, unless explicitly stated in the claims, the order of processing elements and sequences described in the present disclosure, the use of numbers and letters, or the use of other names are not used to limit the sequence of processes and methods in the present disclosure. While the foregoing disclosure has discussed by way of various examples some embodiments of the invention that are presently believed to be useful, it should be understood that such detail is for illustrative purposes only and that the appended claims are not limited to the disclosed embodiments, but rather, the claims The claims are intended to cover all modifications and equivalent combinations that fall within the spirit and scope of the embodiments of the present disclosure. For example, although the system components described above may be implemented by hardware devices, they may also be implemented by a software-only solution, such as installing the described system on an existing server or mobile device.

In the same way, it should be noted that in order to simplify the expression disclosed in the present disclosure and help the understanding of one or more embodiments of the invention, in the foregoing description of the embodiments of the present disclosure, sometimes multiple features are combined into one embodiment, drawings or descriptions thereof. This method of disclosure does not, however, imply that the subject matter of the specification requires more features than are recited in the claims. Indeed, embodiment features are less than all features of a single foregoing disclosed embodiment.

In some embodiments, numbers describing the quantity of components and attributes are used. It should be understood that such numbers used in the description of the embodiments use the modifiers “about”, “approximately” or “substantially” in some examples, grooming. Unless otherwise stated, “about”, “approximately” or “substantially” indicates that the stated figure allows for a variation of ±20%. Correspondingly, in some embodiments, the numerical parameters used in the specification and claims are approximations that may vary depending upon the desired characteristics of individual embodiments. In some embodiments, numerical parameters should take into account the specified significant digits and adopt the general digit reservation method. Although the numerical ranges and parameters used in some embodiments of the present disclosure to confirm the breadth of the range are approximations, in specific embodiments, such numerical values are set as precisely as practicable.

Each patent, patent application, patent application publication, and other material, such as article, book, specification, publication, document, etc., cited in the present disclosure is hereby incorporated by reference in its entirety. Application history documents that are inconsistent with or conflict with the content of the present disclosure are excluded, and documents (currently or later appended to the present disclosure) that limit the broadest scope of the claims of the present disclosure are excluded. It should be noted that if there is any inconsistency or conflict between the descriptions, definitions, and/or terms used in the accompanying materials of the present disclosure and the contents of the present disclosure, the descriptions, definitions and/or terms used in the present disclosure shall prevail.

Finally, it should be understood that the embodiments described in the present disclosure are only used to illustrate the principles of the embodiments of the present disclosure. Other modifications are also possible within the scope of this description. Therefore, by way of example and not limitation, alternative configurations of the embodiments of the present disclosure may be considered consistent with the teachings of the present disclosure. Correspondingly, the embodiments of the present disclosure are not limited to the embodiments explicitly introduced and described in the present disclosure.

1. A signal acquisition device, comprising:
a signal receiving unit configured to process a received magnetic resonance signal, wherein at least part of the magnetic resonance signal is generated by exciting one or more specific nuclides;
an analog-to-digital converter configured to perform an analog-to-digital conversion on the magnetic resonance signal; and
a control unit configured to obtain a digital output signal of the magnetic resonance signal by processing the magnetic resonance signal after the analog-to-digital conversion.

2. The signal acquisition device of claim 1, wherein the signal receiving unit includes: a signal obtaining module and a signal matching module, wherein
the signal obtaining module is connected to the signal matching module, and the signal obtaining module is configured to obtain the magnetic resonance signal; and
the signal matching module includes an adjustable capacitance unit and a radio frequency transformer connected to each other, and the adjustable capacitance unit is configured to adjust a capacitance value according to a first control signal to cooperate with the radio frequency transformer to receive the magnetic resonance signal and convert the magnetic resonance signal into an analog differential signal.

3. The signal acquisition device of claim 2, wherein the signal matching module is connected to the analog-to-digital converter, and the analog-to-digital converter is configured to convert the analog differential signal into a digital signal; and
the analog-to-digital converter is connected to the control unit, and the control unit is configured to process the digital signal to generate the digital output signal corresponding to the magnetic resonance signal, wherein
the control unit includes an analysis unit, and the analysis unit is configured to analyze an instruction of a host computer and generate the first control signal.

4. The signal acquisition device of claim 2, wherein the signal obtaining module includes a plurality of radio frequency receiving units, and each radio frequency receiving unit includes a radio frequency receiving coil and an anti-aliasing filter, wherein
the radio frequency receiving coil is configured to receive a magnetic resonance signal of a specific nuclide frequency, and the anti-aliasing filter is configured to filter the magnetic resonance signal of the specific nuclide frequency.

5. (canceled)

6. The signal acquisition device of claim 2, wherein the adjustable capacitance unit includes one or more varactor components, and each of the one or more varactor components includes two varactor diodes connected in parallel or in series.

7. The signal acquisition device of claim 2, wherein the adjustable capacitance unit includes a plurality of capacitors connected in parallel and at least one switch, and the at least one switch is configured to control access of the plurality of capacitors connected in parallel.

8. The signal acquisition device of claim 2, wherein the radio frequency transformer includes one or more stages of non-magnetic core balun transformers connected in series.

9-12. (canceled)

13. The signal acquisition device of claim 2, further comprising a counter module and a drive circuit, wherein the counter module outputs a digital pulse under control of a third control signal, and a signal for adjusting the adjustable capacitance unit is generated after the digital pulse passing through the drive circuit.

14. The signal acquisition device of claim 2, wherein the signal matching module further includes a power divider, which is configured to perform power division on the magnetic resonance signal and send at least one signal after the power division to the adjustable capacitor unit and the radio frequency transformer.

15. The signal acquisition device of claim 1, comprising a first signal-receiving unit and a second signal-receiving unit, wherein:
the first signal-receiving unit is configured to process a magnetic resonance spectrum signal collected by a first front-end receiving device;
the second signal-receiving unit is configured to process a magnetic resonance imaging signal collected by a second front-end receiving device; and
at least two analog-to-digital converters are configured to perform an analog-to-digital conversion on the magnetic resonance spectrum signal or the magnetic resonance imaging signal.

16. The signal acquisition device of claim 15, wherein the first signal-receiving unit includes a power divider, which is configured to divide the magnetic resonance spectrum signal into at least two power-divided signals;
each of the analog-to-digital converters is configured to generate a power-divided digital signal by performing the analog-to-digital conversion on one of the at least two power-divided signals; and
the control unit is configured to generate the digital output signal corresponding to the magnetic resonance spectrum signal by adding the power-divided digital signals.

17. The signal acquisition device of claim 16, wherein the first signal-receiving unit further includes a frequency mixing circuit configured to divide the magnetic resonance spectrum signal into a first signal and a second signal;
the power divider is configured to divide the first signal into at least two first power-divided signals and divide the second signal into at least two second power-divided signals;
the each of the analog-to-digital converters is configured to convert one of the at least two first power-divided signals into a first power-divided digital signal, or convert one of the at least two second power-divided signals into a second power-divided digital signal; and
the control unit is configured to obtain the digital output signal corresponding to the magnetic resonance spectrum signal by respectively adding at least two first power-divided digital signals and at least two second power-divided digital signals.

18. The signal acquisition device of claim 15, wherein the second signal-receiving unit includes at least two receiving ports configured to receive the magnetic resonance imaging signal collected by the second front-end receiving device.

19. The signal acquisition device of claim 18, wherein one of the at least two receiving ports is a target receiving port to receive a spectrum imaging signal collected by the first front-end receiving device.

20. The signal acquisition device of claim 19, further comprising a second switch unit configured to connect or disconnect a path between the target receiving port and the first signal-receiving unit.

21. The signal acquisition device of claim 15, further comprising a first switch unit configured to connect or disconnect a path between the first signal-receiving unit and the analog-to-digital converters.

22. The signal acquisition device of claim 15, wherein the second signal-receiving unit includes an adjustable capacitance unit and a radio frequency transformer connected to each other, and the adjustable capacitance unit is configured to adjust a capacitance value according to a fourth control signal to cooperate with the radio frequency transformer to receive a magnetic resonance signal and convert the magnetic resonance signal into an analog differential signal.

23. A magnetic resonance signal processing device, configured to process a magnetic resonance spectrum signal collected by a first front-end receiving device, the device comprising:
a power divider configured to divide the magnetic resonance spectrum signal into at least two power-divided signals;
at least two analog-to-digital converters configured to convert the power-divided signals into power-divided digital signals; and
a control unit configured to obtain a digital output signal corresponding to the magnetic resonance spectrum signal by adding the power-divided digital signals.

24. The device of claim 23, further comprising: a frequency mixing circuit configured to divide the magnetic resonance spectrum signal into a first signal and a second signal; wherein
the power divider is configured to divide the first signal into at least two first power-divided signals and divide the second signal into at least two second power-divided signals;
each of the analog-to-digital converters is configured to convert one of the at least two first power-divided signals into a first power-divided digital signal, or convert one of the at least two second power-divided signals into a second power-divided digital signal; and
the control unit is configured to obtain the digital output signal corresponding to the magnetic resonance spectrum signal by respectively adding at least two first power-divided digital signals and at least two second power-divided digital signals.

25. (canceled)

26. A magnetic resonance signal processing device, comprising:
a third signal-receiving unit configured to process a first magnetic resonance signal with a specific frequency;
a fourth signal-receiving unit configured to process a second magnetic resonance signal obtained according to a fifth control signal, the second magnetic resonance signal corresponding to one of a plurality of magnetic resonance frequencies;
at least two analog-to-digital converters configured to perform an analog-to-digital conversion on the first magnetic resonance signal or the second magnetic resonance signal; and
a control unit configured to generate a digital output signal corresponding to the first magnetic resonance signal by processing the first magnetic resonance signal after the analog-to-digital conversion, or generate a digital output signal corresponding to the second magnetic resonance signal by processing the second magnetic resonance signal after the analog-to-digital conversion.
